(19) United States
(12) Patent Application Publication
(10) Pub. No.: US 2026/0080956 A1
(43) Pub. Date: Mar. 19, 2026

(54) SEMICONDUCTOR STORAGE DEVICE, MEMORY SYSTEM, AND METHOD FOR CONTROLLING SEMICONDUCTOR STORAGE DEVICE

(71) Applicant: Kioxia Corporation, Tokyo (JP)

(72) Inventors: Shohei KANAZAWA, Kamakura Kanagawa (JP); Noriyasu KUMAZAKI, Kawasaki Kanagawa (JP); Shuhei OKETA, Yamato Kanagawa (JP); Naoya SHIMMYO, Yokohama Kanagawa (JP)

(73) Assignee: Kioxia Corporation, Tokyo (JP)

(21) Appl. No.: 19/063,044

(22) Filed: Feb. 25, 2025

(30) Foreign Application Priority Data
Sep. 19, 2024 (JP) 2024-162279

(51) Int. Cl. G11C 16/34; G11C 16/04

(52) U.S. Cl. CPC G11C 16/3427; G11C 16/0483

(57) ABSTRACT

A semiconductor storage device includes a first plane and a second plane, a signal line, a determination circuit, and a control unit. The signal line applies voltages to a first word line connected to a first memory cell transistor in a first block of the first plane and a second word line connected to a second memory cell transistor in a second block of the second plane. The determination circuit determines based on a voltage of the signal line whether there is any leakage in the first word line or the second word line. Based on determination results of the determination circuit, the control unit registers the first block as a bad block and registers the second block as a victim block able to be used as a good block.

### CROSS-REFERENCE TO RELATED APPLICATION

This application is based upon and claims the benefit of priority from the prior Japanese Patent Applications No. 2024-162279, filed on Sep. 19, 2024, the entire contents of which are incorporated herein by reference.

### FIELD

An embodiment described herein generally relates to a semiconductor storage device, a memory system, and a method for controlling the semiconductor storage device.

### BACKGROUND

The semiconductor storage device has a multi-plane configuration made up of a plurality of planes and has a multi-plane mode for simultaneously writing data into the plurality of planes.

### BRIEF DESCRIPTION OF THE DRAWINGS

FIG. 1 is a block diagram showing a schematic configuration of a memory system according to an embodiment;

FIG. 2 is a block diagram showing a schematic configuration of a semiconductor storage device according to the embodiment;

FIG. 3 is a block diagram showing a schematic configuration of a register according to the embodiment;

FIG. 4 is a circuit diagram showing a configuration of the semiconductor storage device according to the embodiment;

FIG. 5 is a sectional view showing a sectional structure of the semiconductor storage device according to the embodiment;

FIG. 6 is a diagram showing an example of threshold voltage distributions of a memory cell transistors according to the embodiment;

FIG. 7 is a diagram showing changes in the potentials of various lines during a program operation of the memory cell transistor according to the embodiment;

FIG. 8 is a diagram showing changes in the potentials of various lines during a read operation of the memory cell transistor according to the embodiment;

FIG. 9 is a diagram showing changes in the potentials of word lines during a write operation according to the embodiment;

FIG. 10 is a diagram showing a relationship between loop count and verify operation during a write operation according to the embodiment;

FIG. 11 is a diagram showing a relationship between loop count and program operation during a write operation according to the embodiment;

FIG. 12 is a block diagram showing a schematic configuration of a plane control circuit according to the embodiment;

FIG. 13 is a block diagram showing a schematic configuration of a row decoder according to the embodiment;

FIG. 14 is a diagram schematically showing an operation example of a semiconductor storage device according to a comparative example;

FIG. 15 is a block diagram showing a schematic configuration of a voltage supply circuit according to the embodiment;

FIG. 16 is a flowchart showing an operation example of the semiconductor storage device according to the embodiment;

FIG. 17 is a diagram schematically showing an operation example of the semiconductor storage device according to the embodiment;

FIG. 18 is a diagram schematically showing an operation example of the semiconductor storage device according to the embodiment;

FIG. 19 is a timing chart showing transitions in voltage of a selected word line, voltage of a first global signal line, and output signal of a determination circuit;

FIG. 20 is a diagram schematically showing an operation example of the semiconductor storage device according to the embodiment;

FIG. 21 is a diagram schematically showing an operation example of the semiconductor storage device according to the embodiment;

FIG. 22 is a timing chart showing transitions in voltage of a selected word line, voltage of a first global signal line, and output signal of a determination circuit of the semiconductor storage device according to the embodiment;

FIG. 23 is a flowchart showing an operation example of a memory controller according to the embodiment; and

FIG. 24 is a sectional view showing a sectional structure of the semiconductor storage device according to another embodiment.

### DETAILED DESCRIPTION

In general, according to the embodiment, a semiconductor storage device includes a first plane, a second plane, signal lines, a determination circuit, and a control unit. Each of the first plane and second plane has a plurality of blocks, each of which is a set of a plurality of memory cell transistors. The signal lines apply voltages to first word lines connected to gates of first memory cell transistors contained in a first block of the first plane and second word lines connected to gates of second memory cell transistors contained in a second block of the second plane. The determination circuit determines, based on the voltages of the signal lines, whether there is any leakage in the first word lines or the second word lines. The control unit controls the first plane and the second plane. When determination results produced by the determination circuit indicate that there is leakage in the first word lines but no leakage in the second word lines, the control unit registers the first block as a bad block, and the second block as a victim block able to be used as a good block.

An embodiment will be described below with reference to the accompanying drawings. To facilitate understanding of the description, the same components in different drawings are denoted by the same reference signs whenever possible and redundant description thereof will be omitted.

### 1 Embodiment

The semiconductor storage device according to the embodiment will be described. The semiconductor storage device according to the present embodiment is a nonvolatile storage device configured as a NAND flash memory.

### 1.1 Configuration of Memory System

First, a configuration of a memory system according to the present embodiment will be described.

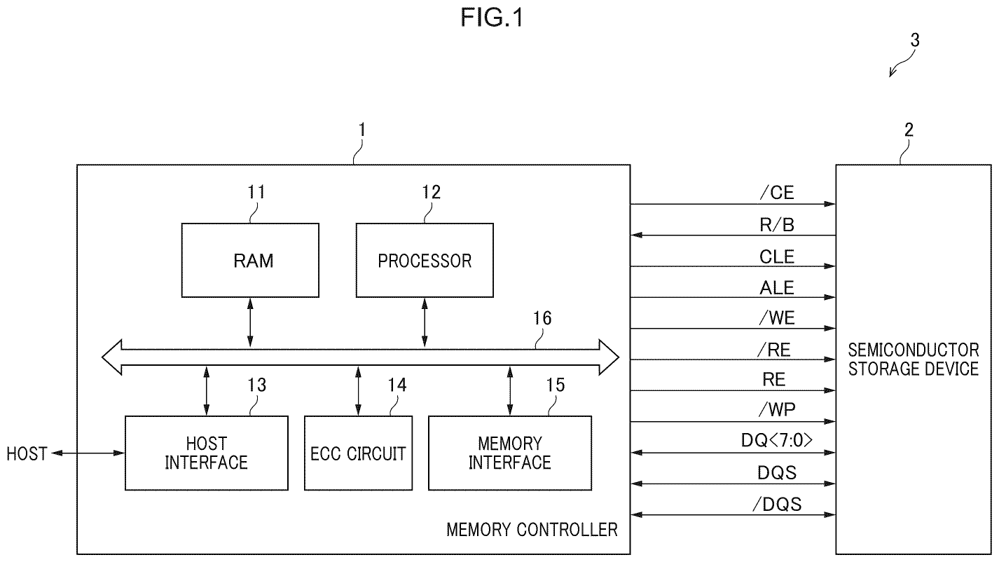

As shown in FIG. 1, the memory system 3 according to the present embodiment includes a memory controller 1 and a semiconductor storage device 2. The memory system 3 is connectable to a host. The host is an electronic device such as a personal computer or a portable terminal.

The memory controller 1 controls writing of data into the semiconductor storage device 2 in response to a write request from the host. The memory controller 1 also controls reading of data from the semiconductor storage device 2 in response to a read request from the host.

Signals are exchanged between the memory controller 1 and the semiconductor storage device 2, including: a chip enable signal /CE, a ready/busy signal R/B, a command latch enable signal CLE, an address latch enable signal ALE, a write enable signal /WE, read enable signals /RE and RE, a write protect signal /WP, a signal DQ <7:0>, and data strobe signals DQS and /DQS.

The chip enable signal /CE is transmitted from the memory controller 1 to the semiconductor storage device 2. The chip enable signal /CE is intended to enable the semiconductor storage device 2. The ready/busy signal R/B is transmitted from the semiconductor storage device 2 to the memory controller 1. The ready/busy signal R/B is intended to indicate whether the semiconductor storage device 2 is in a ready state or in a busy state. The “ready state” is a state in which instructions are accepted from outside, for example. The “busy state” is a state in which instructions are not accepted from outside.

The command latch enable signal CLE is transmitted from the memory controller 1 to the semiconductor storage device 2. The command latch enable signal CLE is intended to indicate that the signal DQ <7:0> is a command. The address latch enable signal ALE is transmitted from the memory controller 1 to the semiconductor storage device 2. The address latch enable signal ALE is intended to indicate that the signal DQ <7:0> is an address. The write enable signal /WE is transmitted from the memory controller 1 to the semiconductor storage device 2. The write enable signal /WE is intended to take a received signal into the semiconductor storage device 2 and is asserted each time the memory controller 1 receives a command, an address, and data. The memory controller 1 instructs the semiconductor storage device 2 to take in the signal DQ <7:0> while the signal /WE is at logic low.

The read enable signal /RE is transmitted from the memory controller 1 to the semiconductor storage device 2. The signal RE is a complementary signal of the signal /RE. The read enable signals /RE and RE are intended for the memory controller 1 to read data from the semiconductor storage device 2. The read enable signals /RE and RE are used to control operation timing of the semiconductor storage device 2 during output, for example, of the signal DQ <7:0>. The signal DQ <7:0> is a substance of data exchanged between the semiconductor storage device 2 and the memory controller 1, and includes a command, an address, and data. The data strobe signal DQS is a timing control signal exchanged between the semiconductor storage device 2 and the memory controller 1 together with the signal DQ <7:0>. The signal /DQS is a complementary signal of the signal DQS. The data strobe signals DQS and /DQS are intended to control input-output timing of the signal DQ <7:0>.

The memory controller 1 includes a RAM 11, a processor 12, a host interface 13, an ECC circuit 14, and a memory interface 15, which are interconnected via an internal bus 16.

The host interface 13 outputs a request received from the host, user data (write data), and the like to the internal bus 16. The host interface 13 also transmits user data read out of the semiconductor storage device 2, a response from the processor 12, and the like to the host.

The memory interface 15 controls the process of writing user data and the like into the semiconductor storage device 2 and the process of reading user data and the like from the semiconductor storage device 2 on instructions from the processor 12.

The processor 12 exerts overall control over the memory controller 1. The processor 12 is a CPU, an MPU, or the like. When a request is received from the host via the host interface 13, the processor 12 performs control according to the request. For example, in response to the request from the host, the processor 12 instructs the memory interface 15 to write user data and parity into the semiconductor storage device 2. In response to the request from the host, the processor 12 also instructs the memory interface 15 to read the user data and parity from the semiconductor storage device 2.

The processor 12 determines a storage area (memory area) on the semiconductor storage device 2 for the user data accumulated in the RAM 11. The user data is stored in the RAM 11 via the internal bus 16. The processor 12 determines the memory areas for data (page data) managed in the unit of writing, i.e., on a page-by-page basis. Hereinafter, the user data stored on one page of the semiconductor storage device 2 will also be referred to as “unit data.” Generally, the unit data is encoded, and stored as code words in the semiconductor storage device 2. According to the present embodiment, encoding is not essential. The memory controller 1 may store the unit data in the semiconductor storage device 2 without encoding, but FIG. 1 shows as an example a configuration in which encoding is done.

The processor 12 determines a memory area of the semiconductor storage device 2 at the write destination for each unit data item. Physical addresses have been assigned to the memory areas of the semiconductor storage device 2. The processor 12 manages the memory areas at the write destinations for unit data using the physical addresses. By specifying determined memory areas (physical addresses), the processor 12 instructs the memory interface 15 to write user data into the semiconductor storage device 2. The processor 12 manages correspondence between logical addresses (the logical addresses managed by the host) and the physical addresses of the user data. When a read request containing a logical address from the host is received, the processor 12 identifies the physical address corresponding to the logical address and instructs the memory interface 15 to read the user data, by specifying the physical address.

The ECC circuit 14 encodes the user data stored in the RAM 11, and thereby generates code words. The ECC circuit 14 also decodes the code words read out of the semiconductor storage device 2.

The RAM 11 temporarily stores the user data received from the host, before storing the user data in the semiconductor storage device 2 and temporarily stores the data read out of the semiconductor storage device 2, before transmitting the data to the host. The RAM 11 is a general-purpose memory such as a SRAM or a DRAM.

FIG. 1 shows a configuration example in which the memory controller 1 includes the ECC circuit 14 and the memory interface 15. However, the ECC circuit 14 may be incorporated in the memory interface 15. Alternatively, the ECC circuit 14 may be incorporated in the semiconductor storage device 2. Specific configurations and arrangements of the components shown in FIG. 1 are not particularly limited.

When a write request is received from the host, the memory system 3 in FIG. 1 operates as follows. The processor 12 temporarily stores the write data in the RAM 11. The processor 12 reads the data stored in the RAM 11 and inputs the data to the ECC circuit 14. The ECC circuit 14 encodes the input data and inputs code words to the memory interface 15. The memory interface 15 writes the input code words in the semiconductor storage device 2.

When a read request is received from the host, the memory system 3 in FIG. 1 operates as follows. The memory interface 15 inputs the code words read out of the semiconductor storage device 2 to the ECC circuit 14. The ECC circuit 14 decodes the input code words and stores the resulting data in the RAM 11. The processor 12 transmits the data stored in the RAM 11 to the host via the host interface 13.

### 1.2 Schematic Configuration of Semiconductor Storage Device

Next, a schematic configuration of the semiconductor storage device 2 will be described.

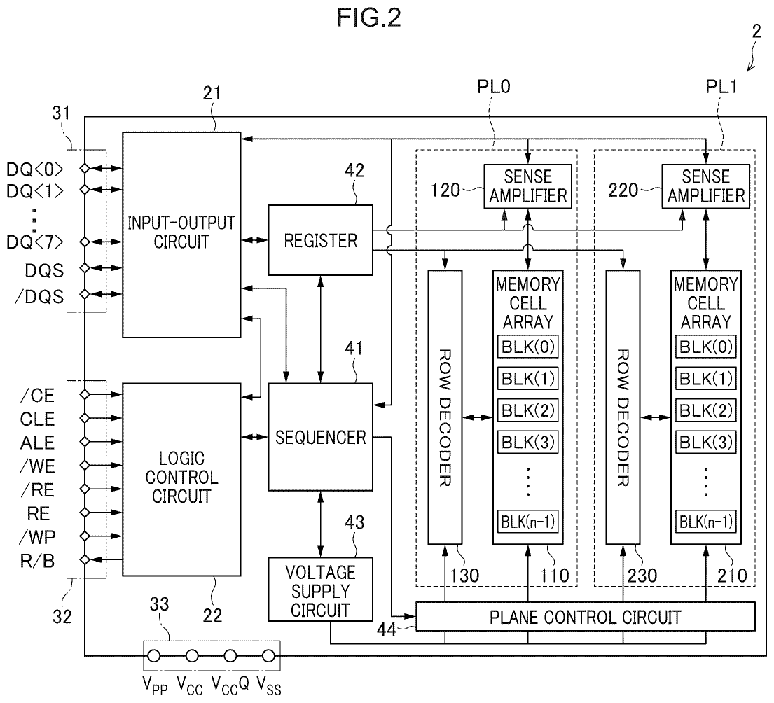

FIG. 2 is a block diagram showing a configuration of the semiconductor storage device 2. As shown in FIG. 2, the semiconductor storage device 2 includes two planes PL0 and PL1, an input-output circuit 21, a logic control circuit 22, a sequencer 41, a register 42, a voltage supply circuit 43, a plane control circuit 44, an input/output pad group 31, a logic control pad group 32, and a power input terminal group 33.

The plane PL0 includes a memory cell array 110, a sense amplifier 120, and a row decoder 130. The other plane PL1 similarly includes a memory cell array 210, a sense amplifier 220, and a row decoder 230. The planes PL0 and PL1 have the same configuration.

The memory cell arrays 110 and 210 are parts configured to store data. Each of the memory cell arrays 110 and 210 includes a plurality of memory cell transistors linked to word lines and bit lines. Each of the planes PL0 and PL1 includes a plurality of blocks BLK(BLK(0), BLK(1), . . . , BLK(n−1)), where “n” is an integer that indicates the number of blocks included in each of the planes PL0 and PL1. Each of the blocks BLK functions as a unit of erase operation. The semiconductor storage device 2 has a multi-plane configuration whereby write operations are performed simultaneously on a plurality of planes PL0 and PL1.

The input-output circuit 21 exchanges the signal DQ <7:0> and the data strobe signals DQS and /DQS with the memory controller 1. The input-output circuit 21 transfers a command and an address in the signal DQ <7:0> to the register 42. The input-output circuit 21 also exchanges write data and read data with the sense amplifier 120 and 220.

The logic control circuit 22 receives the chip enable signal /CE, the command latch enable signal CLE, the address latch enable signal ALE, the write enable signal /WE, the read enable signals /RE and RE, and the write protect signal /WP from the memory controller 1. The logic control circuit 22 transfers the ready/busy signal R/B to the memory controller 1 and informs the outside about the state of the semiconductor storage device 2.

The sequencer 41 controls operations of the planes PL0 and PL1, the voltage supply circuit 43, and other components based on control signals input to the input-output circuit 21 and the logic control circuit 22 from the memory controller 1. According to the present embodiment, the sequencer 41 is an example of a control unit.

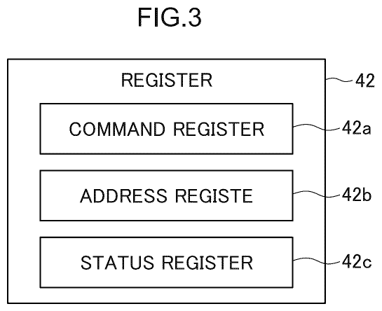

The register 42 is a part configured to temporarily hold commands, addresses, and the like. As shown in FIG. 3, the register 42 includes a command register 42a, an address register 42b, and a status register 42c.

The command register 42a is a part configured to hold commands for use to instruct the planes PL0 and PL1 to perform write operations, read operations, erase operations, and other operations. The commands are input to the input-output circuit 21 from the memory controller 1, and then transferred from the input-output circuit 21 to the command register 42a and held there. The command register 42a transfers the held commands to the sequencer 41.

The address register 42b is a part configured to hold respective addresses of the planes PL0 and PL1 at which commands for the planes PL0 and PL1 are to be sent. For example, when the addresses of the planes PL0 and PL1 are input to the input-output circuit 21 from the memory controller 1, the addresses are transferred from the input-output circuit 21 to the address register 42b. The address register 42b transfers a block address and row address included in the address of the plane PL0 to the row decoder 130 of the plane PL0. The address register 42b also transfers a block address and row address included in the address of the plane PL1 to the row decoder 230 of the plane PL1.

The status register 42c is a part configured to store status information that represents respective states of the planes PL0 and PL1. The status information is updated by the sequencer 41 as needed according to respective operating states of the planes PL0 and PL1. The status information stored in the status register 42c is transmitted as status signals from the input-output circuit 21 to the memory controller 1 in response to requests from the memory controller 1.

On instructions from the sequencer 41, the voltage supply circuit 43 shown in FIG. 2 generates voltages necessary for write operations, read operations, and erase operations, and supplies the generated voltages to the row decoders 130 and 230 and the sense amplifiers 120 and 220.

The plane control circuit 44 is made up of a switch circuit group for use to control the voltages supplied from the voltage supply circuit 43 to the row decoders 130 and 230. By switching between open and closed states of the switch circuit group, the plane control circuit 44 can switch between, for example, a state in which voltages are supplied from the voltage supply circuit 43 to the row decoders 130 and 230 and a state in which voltage supply from the voltage supply circuit 43 to the row decoders 130 and 230 is shut off. The plane control circuit 44 is controlled by the sequencer 41.

The sense amplifier 120 of the plane PL0 is a circuit intended to adjust the voltage applied to the bit lines of the memory cell array 110 as well as to read the voltages of the bit lines of the memory cell array 110 and convert the voltages into data. During a data read, the sense amplifier 120 acquires data read to the bit lines from the memory cell transistors of the memory cell array 110 and transfers the acquired read data to the input-output circuit 21. During a data write, the sense amplifier 120 transfers the data written via the bit lines to the memory cell transistors of the memory cell array 110.

The row decoder 130 of the plane PL0 is a circuit intended to apply voltages to a plurality of word lines and a plurality of select gate lines in any of the blocks BLK included in the memory cell array 110, respectively. The row decoder 130 receives the block address and row address corresponding to the plane PL0 from the address register 42b of the register 42, selects a block of the memory cell array 110 based on the block address, and selects word lines of the memory cell array 110 based on the row address. The row decoder 130 switches the open/closed states of a switch group such that voltages will be supplied to the selected word lines from the voltage supply circuit 43.

The sense amplifier 220 of the plane PL1 performs an operation similar to the sense amplifier 120 of the plane PL0 on the memory cell array 210 of the plane PL1. The row decoder 230 of the plane PL1 performs an operation similar to the row decoder 130 of the plane PL0 on the memory cell array 210 of the plane PL1. The operations of the sense amplifiers 120 and 220 and the operations of the row decoders 130 and 230 are controlled by the sequencer 41.

The input/output pad group 31 is made up of a plurality of terminals (pads) for use to exchange various signals between the memory controller 1 and the input-output circuit 21. The terminals are provided individually for the signal DQ <7:0> and the data strobe signals DQS and /DQS.

The logic control pad group 32 is made up of a plurality of terminals (pads) for use to exchange various signals between the memory controller 1 and the logic control circuit 22. The terminals are provided individually for the chip enable signal /CE, the command latch enable signal CLE, the address latch enable signal ALE, the write enable signal /WE, the read enable signals /RE and RE, the write protect signal /WP, and the ready/busy signal R/B.

The power input terminal group 33 is made up of a plurality of terminals through which various voltages necessary for operations of the semiconductor storage device 2 are applied. The voltages applied to the respective terminals include power supply voltages Vcc, VccQ, and Vpp and a ground voltage Vss. The power supply voltage Vcc is a circuit power supply voltage provided externally as an operating power supply voltage and is, for example, around 3.3 V. The power supply voltage VccQ is, for example, around 1.2 V. The power supply voltage VccQ is used in exchanging signals between the memory controller 1 and the semiconductor storage device 2. The power supply voltage Vpp is higher than the power supply voltage Vcc and is, for example, around 12 V.

Note that at least one of the plurality of blocks BLK included in each of the memory cell arrays 110 and 210 functions as a ROM block. The ROM block stores data necessary for operations of the semiconductor storage device 2, such as various operation parameters, rather than user data. The ROM block also contains state information (good-block/bad-block information), which indicates whether the pluralities of blocks BLK provided in the respective memory cell arrays 110 and 210 are normal or defective. The user is inhibited from instructing user data to be written into the ROM block or from instructing data stored in the ROM block to be erased. In other words, in each of the memory cell arrays 110 and 210, aside from areas in which data can be written or erased externally, the ROM block is provided specially as a storage area in which data cannot be written or erased externally.

With the memory system 3 according to the present embodiment, upon application of a power supply voltage to the memory system 3, the semiconductor storage device 2 performs a power-on-read process. Specifically, when the power supply voltage is applied to the memory system 3, the processor 12 of the memory controller 1 shown in FIG. 1 instructs the semiconductor storage device 2 via the memory interface 15 to perform a power-on-read process. Consequently, in the semiconductor storage device 2, data is read from, for example, the ROM blocks provided, respectively, in the memory cell arrays 110 and 210, and stored in a register of the sequencer 41. Consequently, the semiconductor storage device 2 becomes capable of operating properly, i.e., the semiconductor storage device 2 becomes activated. The good-block/bad-block information read out of the ROM blocks is transmitted to the memory controller 1 via the input-output circuit 21 and stored in the RAM 11 shown in FIG. 1. Based on the good-block/bad-block information stored in the RAM, the memory controller 1 instructs the semiconductor storage device 2 to operate in such a way as to avoid defective blocks.

### 1.3 Circuit Configurations of Memory Cell Arrays

Next, circuit configurations of the memory cell arrays 110 and 210 will be described. Note that the memory cell arrays 110 and 210 are identical in configuration, and thus the configuration of only the memory cell array 110 will be described below, and description of the memory cell array 210 will be omitted.

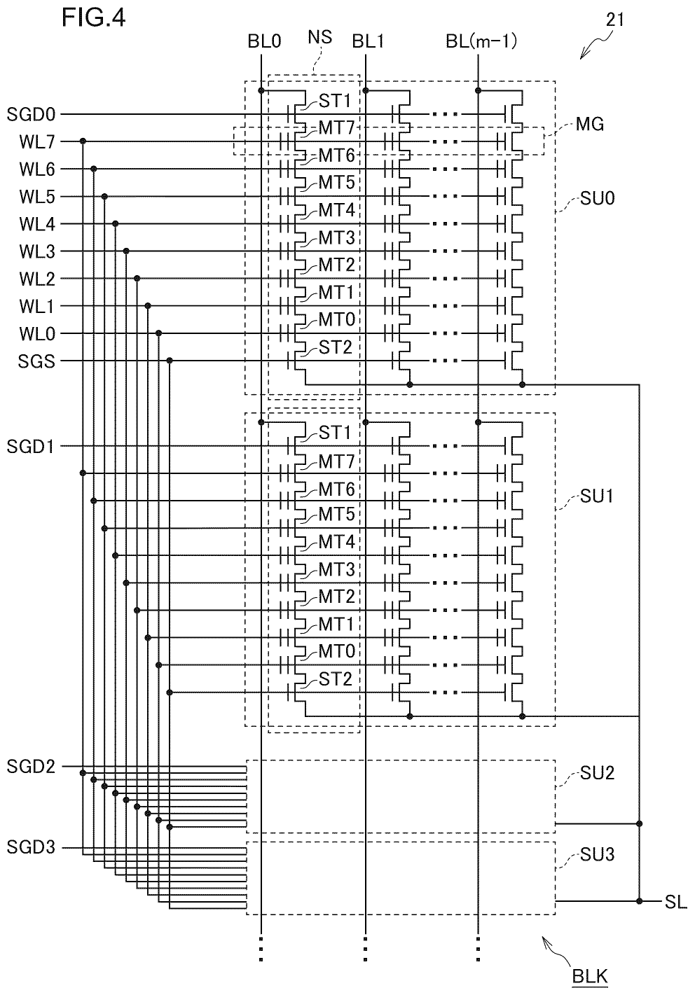

As shown in FIG. 4, the memory cell array 110 is made up of a plurality of blocks BLK. In FIG. 4, only one of the plurality of blocks BLK is illustrated. The other blocks BLK of the memory cell array 110 are similar in configuration to the block BLK shown in FIG. 4.

As shown in FIG. 4, the block BLK includes, for example, four string units SU (SU0 to SU3). Each of the string units SU includes a plurality of NAND strings NS. Each of the NAND strings NS includes, for example, eight memory cell transistors MT (MT0 to MT7) and selection transistors ST1 and ST2.

The memory cell transistors MT are placed, being connected in series between the selection transistor ST1 and the selection transistor ST2. The memory cell transistor MT7 at one end is connected to a source of the selection transistor ST1, and the memory cell transistor MT0 at the other end is connected to a drain of the selection transistor ST2.

Gates of the selection transistors ST1 in the respective string units SU0 to SU3 are commonly connected to respective select gate lines SGD0 to SGD3. Gates of the selection transistors ST2 are commonly connected to the same select gate line SGS among a plurality of string units SU in the same block BLK. Gates of the memory cell transistors MT0 to MT7 in the same block BLK are commonly connected to respective word lines WL0 to WL7. That is, the word lines WL0 to WL7 and the select gate line SGS are common among the plurality of string units SU0 to SU3 in the same block BLK, but the select gate lines SGD are provided individually for each of the string units SU0 to SU3 even in the same block BLK.

Bit lines BL (BL0, BL1, . . . , BL(m−1)), m in number, are provided in the memory cell array 110, where “m” is an integer corresponding to the number of NAND strings NS included in one string units SU0. A drain of each selection transistor ST1 in the NAND strings NS is connected to a corresponding bit line BL. A source of each selection transistor ST2 in the NAND strings NS is connected to a source line SL. The source line SL is common to the sources of a plurality of the selection transistors ST2 in the block BLK.

Data stored in a plurality of the memory cell transistors MT in the same block BLK is erased in batches. On the other hand, data reads and data writes are performed in batches with respect to a plurality of the memory cell transistors MT that are connected to one word line WL and belong to one string unit SU.

Each of the memory cell transistors MT can store three-bit data made up of a high-order bit, a middle-order bit, and a low-order bit. That is, as a method of writing data into the memory cell transistor MT, the semiconductor storage device 2 according to the present embodiment adopts a TLC system that allows three bits of data to be stored in a single memory cell transistor MT. As a method of writing data into the memory cell transistor MT, instead of such a form, it is possible to adopt a system such as an MLC system that allows two bits of data to be stored in a single memory cell transistor MT or an SLC system that allows one bit of data to be stored in a single memory cell transistor MT.

Hereinafter, a set of one-bit data stored in a plurality of the memory cell transistors MT connected to one word line WL and belonging to one string unit SU will be referred to as a “page.” In FIG. 4, one of sets of a plurality of memory cell transistors MT such as described above is marked with the reference sign “MG.”

When three bits of data are stored in a single memory cell transistor MT as with the present embodiment, a set of a plurality of memory cell transistors MT connected to a word line WL common in one string unit SU can store three pages of data.

### 1.4 Sectional Structure of Semiconductor Storage Device

Next, the memory cell arrays 110 and 210 and a structure therearound will be described. Note that the memory cell arrays 110 and 210 are identical in configuration, and thus the configuration of only the memory cell array 110 will be described below, and description of the memory cell array 210 will be omitted.

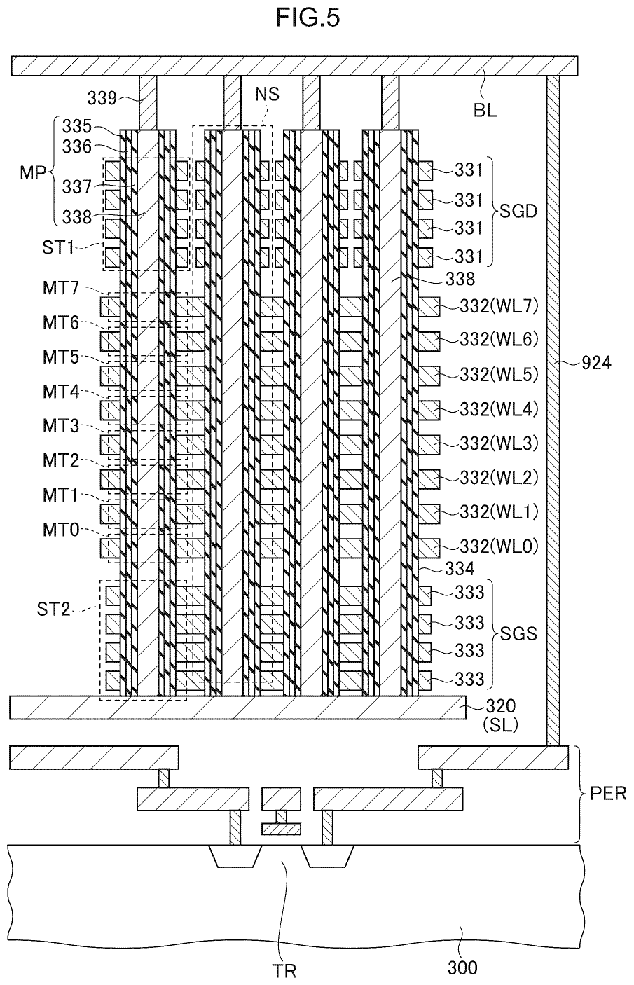

As shown in FIG. 5, in the memory cell array 110, a plurality of NAND strings NS are formed on a conductor layer 320. The conductor layer 320 is also referred to as a buried source line (BSL) and corresponds to the source line SL shown in FIG. 4.

A plurality of interconnect layers 333 functioning as the select gate line SGS, a plurality of interconnect layers 332 functioning as word lines WL, and a plurality of interconnect layers 331 functioning as a select gate line SGD are stacked above the conductor layer 320. Non-illustrated insulating layers are placed among the stacked interconnect layers 333, 332, and 331.

A plurality of memory holes 334 are formed in the memory cell array 110. The memory holes 334 penetrate vertically through the interconnect layers 333, 332, and 331 and through the non-illustrated insulating layers placed among the interconnect layers, reaching the conductor layer 320. A block insulator 335, a charge storage layer 336, and a gate insulator 337 are formed on a side face of each memory hole 334 in sequence, and moreover a conductor pillar 338 is embedded on the inner side thereof. The conductor pillar 338 is made, for example, of polysilicon, and functions as a region in which channels are formed during operation of the memory cell transistors MT and selection transistors ST1 and ST2 included in the NAND string NS. Hereinafter, a columnar body made up of the block insulator 335, the charge storage layer 336, the gate insulator 337, and the conductor pillar 338 on the inner side of each memory hole 334 will also be referred to as a memory pillar MP.

Of the memory pillar MP, parts intersecting the stacked interconnect layers 333, 332, and 331, respectively, function as transistors. Of the plurality of transistors, those located at intersections with the interconnect layers 331 function as the selection transistors ST1. Of the plurality of transistors, those located at intersections with the interconnect layers 332 function as the memory cell transistors MT (MT0 to MT7). Of the plurality of transistors, those located at intersections with the interconnect layers 333 function as the selection transistors ST2. Thanks to this configuration, the memory pillars MP function as the NAND strings NS shown in FIG. 4. The conductor pillars 338 located on the inner side of the memory pillars MP function as channels of the memory cell transistors MT or selection transistors ST1 and ST2.

An interconnect layer functioning as a bit line BL is formed above the conductor pillars 338. Contact plugs 339 connecting the conductor pillars 338 with the bit line BL are formed on upper ends of the conductor pillars 338.

A plurality of structures with a configuration similar to the one shown in FIG. 5 are arranged in the direction away from the viewer in FIG. 5. A set of the plurality of NAND strings NS lined up in the direction away from the viewer in FIG. 5 makes up one string unit SU.

In the semiconductor storage device 2 according to the present embodiment, peripheral circuitry PER is provided below the memory cell array 110, i.e., in a location between the memory cell array 110 and a semiconductor substrate 300. The peripheral circuitry PER is provided to implement data write, data read, data erase, and other operations in the memory cell array 110. The peripheral circuitry PER includes the sense amplifier 120, the row decoder 130, the voltage supply circuit 43, the plane control circuit 44, and the like shown in FIG. 2. The peripheral circuitry PER includes various types of transistors, RC circuits, and the like. In the example shown in FIG. 5, transistors TR formed on the semiconductor substrate 300 and the bit line BL located above the memory cell array 110 are electrically connected with each other via a contact 924.

### 1.5 Threshold Voltage Distributions of Memory Cell Transistors

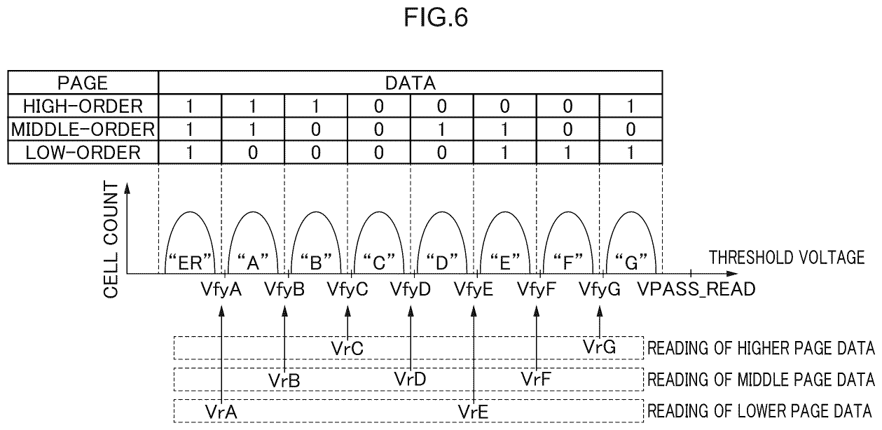

Next, threshold voltage distributions of the memory cell transistors MT will be described. FIG. 6 is a diagram schematically showing threshold voltage distributions and the like of the memory cell transistors MT. The illustration in the middle part of FIG. 6 shows correspondence between the threshold voltage of the memory cell transistor MT (the abscissa) and the number of memory cell transistors MT (the ordinate).

When the TLC system is adopted as with the present embodiment, the plurality of memory cell transistors MT form eight threshold voltage distributions as shown in the middle part of FIG. 6. The eight threshold voltage distributions (i.e., writing levels) are “ER” level, “A” level, “B” level, “C” level, “D” level, “E” level, “F” level, and “G” level in ascending order of the threshold voltage.

The table in the upper part of FIG. 6 shows an example of data assigned in correspondence to the respective threshold voltage levels. As shown in the table, different three-bit data have been assigned, respectively, to the “ER” level, “A” level, “B” level, “C” level, “D” level, “E” level, “F” level, and “G” level, for example, as shown below.
“ER” level: “111” (“low-order bit/middle-order bit/high-order bit)
“A” level: “011”
“B” level: “001”
“C” level: “000”
“D” level: “010”
“E” level: “110”
“F” level: “100”
“G” level: “101”

In this way, the threshold voltage of the memory cell transistor MT according to the present embodiment can take one of eight predetermined candidate levels and data is assigned to each candidate level as described above.

Verify voltages used for write operations are set between respective pairs of adjacent threshold voltage distributions. Specifically, verify voltages VfyA, VfyB, VfyC, VfyD, VfyE, VfyF, and VfyG are set for the “A” level, “B” level, “C” level, “D” level, “E” level, “F” level, and “G” level, respectively.

The verify voltage VfyA is set between a maximum threshold voltage at the “ER” level and a minimum threshold voltage at the “A” level. When the verify voltage VfyA is applied to a word line WL, of the memory cell transistors MT connected to the word line WL, the memory cell transistors MT, the threshold voltages of which are within the “ER” level are turned on and the memory cell transistors MT, the threshold voltages of which are included in the threshold voltage distributions at or above the “A” level are turned off.

The other verify voltages VfyB, VfyC, VfyD, VfyE, VfyF, and VfyG are set in a manner similar to the verify voltage VfyA. The verify voltage VfyB is set between the “A” level and the “B” level, the verify voltage VfyC is set between the “B” level and the “C” level, the verify voltage VfyD is set between the “C” level and the “D” level, the verify voltage VfyE is set between the “D” level and the “E” level, the verify voltage VfyF is set between the “E” level and the “F” level, and the verify voltage VfyG is set between the “F” level and the “G” level.

For example, the verify voltages VfyA, VfyB, VfyC, VfyD, VfyE, VfyF, and VfyG may be set to 0.8 V, 1.6 V, 2.4 V, 3.1 V, 3.8 V, 4.6, V, and 5.6 V, respectively. However, this is not restrictive, and the verify voltages VfyA, VfyB, VfyC, VfyD, VfyE, VfyF, and VfyG may be set, for example, in stages in a range of 0 V to 7.0 V, as appropriate.

Besides, read voltages used for read operations are set between respective pairs of adjacent threshold voltage distributions. The “read voltages” are voltages applied to the word line WL connected to the memory cell transistors MT to be read during read operations, i.e., a selected word line. In read operations, data is determined based on determination results as to whether the threshold voltages of the memory cell transistors MT to be read are higher than applied read voltages.

As schematically shown in the illustration in the lower part of FIG. 6, specifically, a read voltage VrA used to determine whether the threshold voltages of the memory cell transistors MT are within the “ER” level or at or above the “A” level is set between the maximum threshold voltage at the “ER” level and the minimum threshold voltage at the “A” level.

The other read voltages VrB, VrC, VrD, VrE, VrF, and VrG are set in a manner similar to the read voltage VrA. The read voltage VrB is set between the “A” level and the “B” level, the read voltage VrC is set between the “B” level and the “C” level, the read voltage VrD is set between the “C” level and the “D” level, the read voltage VrE is set between the “D” level and the “E” level, the read voltage VrF is set between the “E” level and the “F” level, and the read voltage VrG is set between the “F” level and the “G” level.

Then, a read pass voltage VPASS_READ is set to a voltage higher than the maximum threshold voltage of the highest threshold voltage distribution (e.g., “G” level). The memory cell transistors MT are turned on regardless of the data stored in them when the read pass voltage VPASS_READ is applied to their gates.

Note that the verify voltages VfyA, VfyB, VfyC, VfyD, VfyE, VfyF, and VfyG are set higher than, for example, the read voltages VrA, VrB, VrC, VrD, VrE, VrF, and VrG, respectively. That is, the verify voltages VfyA, VfyB, VfyC, VfyD, VfyE, VfyF, and VfyG are set in the vicinities of lower hems of the threshold voltage distributions at the “A” level, “B” level, “C” level, “D” level, “E” level, “F” level, and “G” level, respectively.

When data assignment such as described above is applied in read operations, one-page data (lower page data) of low-order bits can be confirmed based on read results produced using the read voltages VrA and VrE. One-page data (middle page data) of middle-order bits can be confirmed based on read results produced using the read voltages VrB VrD, and VrF. One-page data (higher page data) of high-order bits can be confirmed based on read results produced using the read voltages VrC and VrG. In this way, since lower page data, middle page data, and higher page data are confirmed by two, three, and two read operations, respectively, data assignment such as described above is referred to as “2-3-2 code.”

### 1.6 Changes in Potentials of Various Lines During Write Operations of Semiconductor Storage Device

Next, the write operation of the semiconductor storage device 2 will be described. In the write operation, program operations and verify operations are performed. The “program operation” is the operation of injecting electrons into charge storage layers 336 of some of the memory cell transistors MT and thereby changing the threshold voltages of the memory cell transistors MT. The “verify operation” is the operation of reading data after the program operation and thereby determining and verifying whether the threshold voltages of the memory cell transistors MT have reached a target level. The memory cell transistors MT, the threshold voltages of which have reached the target level are subsequently write-protected. The “target level” referred to herein is a specific candidate level set as a targeted level among the eight candidate levels described earlier.

In the write operation, the program operation and verify operation are performed repeatedly. This raises the threshold voltages of the memory cell transistors MT to the target level.

Of the plurality of word lines WL, word lines WL connected to memory cell transistors MT to be subjected to a write operation (i.e., to be subjected to changes in threshold voltage) will also be referred to as a “selected word line” hereinafter. On the other hand, word lines WL connected to memory cell transistors MT not subjected to a write operation will also be referred to as “unselected word lines” hereinafter. Memory cell transistors MT to be subjected to writing will also be referred to as “selected memory transistors” hereinafter.

Of the plurality of string units SU, string units SU to be subjected to a write operation will also be referred to as “selected string units” hereinafter. On the other hand, string units SU not subjected to a write operation will also be referred to as “unselected string units” hereinafter.

The conductor pillar 338 of each NAND string NS included in the selected string unit, i.e., each channel of the selected string unit will also be referred to as a “selected channel” hereinafter. The conductor pillar 338 of each NAND string NS included in the unselected string unit, i.e., each channel of the unselected string unit will also be referred to as an “unselected channel” hereinafter.

Of the plurality of bit lines BL bit lines BL connected to the selected memory transistors will also be referred to as “selected bit lines” hereinafter. Bit lines BL not connected to the selected memory transistors will also be referred to as “unselected bit lines” hereinafter.

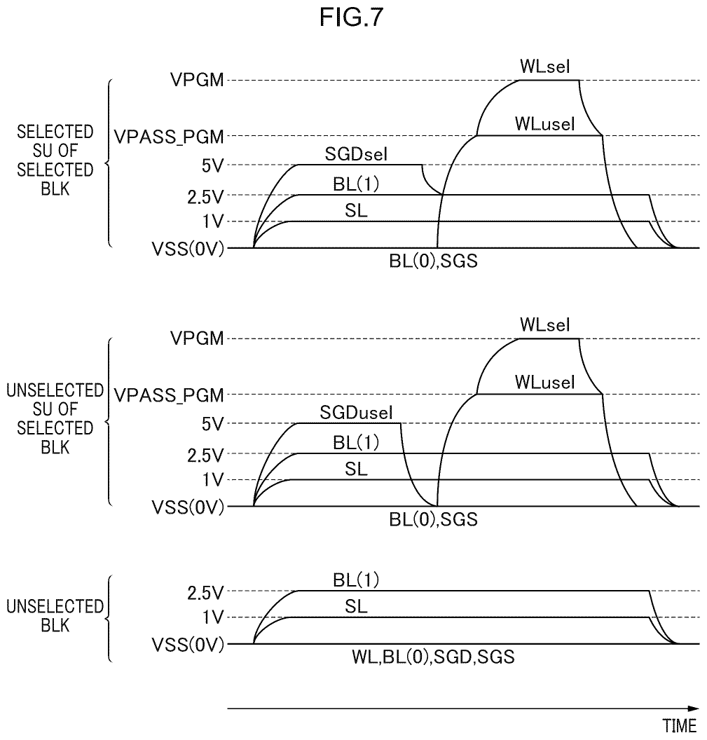

FIG. 7 shows changes in the potentials of various lines during a program operation. In the program operation, the sense amplifiers 120 and 220 change the potentials of respective bit lines BL according to program data. For example, the ground voltage Vss (0 V) is applied as an “L” level voltage to the bit lines BL connected to the memory cell transistors MT to be programmed (the memory cell transistors MT, of which the threshold voltages are to be raised). For example, 2.5 V is applied as an “H” level voltage to the bit lines BL connected to the memory cell transistors MT not to be programmed (the memory cell transistors MT, of which the threshold voltages are to be maintained). The former bit lines BL are denoted as “BL(0)” in FIG. 7. The latter bit lines BL are denoted as “BL(1)”in FIG. 7.

The row decoders 130 and 230 select any of the blocks BLK for write operation and further select any of the string units SU. More specifically, for example, 5 V is applied to the select gate line SGD in the selected string unit SU (selected select gate line SGDsel) from the voltage supply circuit 43 via the row decoders 130 and 230. Consequently, the selection transistor ST1 is turned on. On the other hand, for example, the voltage Vss is applied to the select gate line SGS from the voltage supply circuit 43 via the row decoders 130 and 230. Consequently, the selection transistor ST2 is turned off.

Besides, for example, 5 V is applied to the select gate line SGD in the unselected string unit SU (unselected select gate line SGDusel) in a selected block BLK from the voltage supply circuit 43 via the row decoders 130 and 230. Consequently, the selection transistor ST1 is turned on. Note that the select gate lines SGS are commonly connected in the string units SU included in each block BLK. Therefore, the selection transistor ST2 is turned off in the unselected string unit SU as well.

Furthermore, for example, the voltage Vss is applied to the select gate lines SGD and select gate line SGS in each unselected block BLK from the voltage supply circuit 43 via the row decoders 130 and 230. Consequently, the selection transistor ST1 and the selection transistor ST2 are turned off.

The source line SL is higher in potential than the select gate line SGS. The potential of the source line SL is, for example, 1 V.

Subsequently, the potential of the selected select gate line SGDsel in the selected block BLK is set, for example, to 2.5 V. The potential is a voltage potential that turns on the selection transistor ST1 corresponding to the bit line BL(0) given 0 V in the above example, but cuts off the selection transistor ST1 corresponding to the bit line BL(1) given 2.5 V. Consequently, in the selected string unit SU, the selection transistor ST1 corresponding to the bit line BL(0) is turned on and the selection transistor ST1 corresponding to the bit line BL(1) given 2.5 V is cut off. On the other hand, the potential of the unselected select gate line SGDusel is set, for example, to the voltage Vss. Consequently, in the unselected string unit SU, the selection transistor ST1 is cut off regardless of the potentials of the bit line BL(0) and bit line BL(1).

Then, in the selected block BLK, the row decoders 130 and 230 select any of the word lines WL for write operation. For example, a program voltage VPGM is applied to the word line WL for the write operation (selected word line WLsel) from the voltage supply circuit 43 via the row decoders 130 and 230. On the other hand, for example, a program pass voltage VPASS_PGM is applied to the other word lines WL (unselected word lines WLusel) from the voltage supply circuit 43 via the row decoders 130 and 230. The program voltage VPGM is a high voltage intended to inject electrons into the charge storage layer 336 by tunneling. The program pass voltage VPASS_PGM turns on the memory cell transistors MT connected to the word line WL without changing the threshold voltages. VPGM is higher than VPASS_PGM.

In the NAND strings NS corresponding to the bit lines BL (0) targeted for programming, the selection transistors ST1 are turned on. Therefore, channel potentials of the memory cell transistors MT connected to the selected word line WLsel become 0 V. The potential difference between control gate and channel increases, causing electrons to be injected into the charge storage layer 336, and thereby raising the threshold voltages of the memory cell transistors MT.

In the NAND strings NS corresponding to the bit lines BL (0) not targeted for programming, the selection transistors ST1 are cut off. Therefore, the channels of the memory cell transistors MT connected to the selected word line WLsel become electrically floated, causing channel potentials to increase close to the program voltage VPGM due to capacitive coupling with word lines WL and the like. The potential difference between control gate and channel decreases. Consequently, electrons are not injected into the charge storage layer 336, and thus, the threshold voltages of the memory cell transistors MT are maintained. More precisely, the threshold voltages do not change so greatly as to cause threshold voltage distributions to move to a higher level.

Note that the operation of applying a 5-V voltage to the selected select gate line SGDsel and the unselected select gate line SGDusel in an initial stage of the program operation may be omitted.

The verify operation performed after the program operation is identical to the read operation described below, and thus description thereof will be omitted.

### 1.7 Changes in Potentials of Various Lines During Read Operation of Semiconductor Storage Device

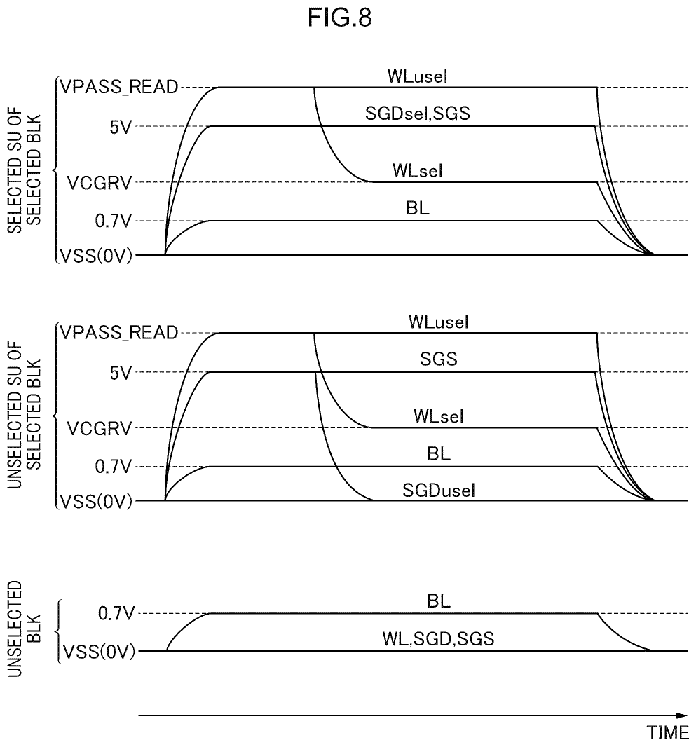

Next, the read operation of the semiconductor storage device 2 will be described. FIG. 8 shows changes in the potentials of various lines during a read operation. In the read operation, the NAND strings NS including the memory cell transistors MT to be subjected to the read operation are selected. Alternatively, the string unit SU containing the pages to be subjected to the read operation are selected.

First, for example, 5 V is applied to the selected select gate line SGDsel, the unselected select gate line SGDusel, and the select gate line SGS from the voltage supply circuit 43 via the row decoders 130 and 230. Consequently, the selection transistor ST1 and the selection transistor ST2 included in the selected block BLK are turned on. Besides, for example, the read pass voltage VPASS_READ is applied to the selected word line WLsel and the unselected word lines WLusel from the voltage supply circuit 43 via the row decoders 130 and 230. The read pass voltage VPASS_READ can turn on the memory cell transistors MT regardless of the threshold voltages of the memory cell transistors MT without changing the threshold voltages. Consequently, both in the case of a selected string unit SU and an unselected string unit SU, electrical current is conducted in all the NAND strings NS included in the selected block BLK.

Next, for example, a read voltage VCGRV such as VrA is applied to the word line WL (selected word line WLsel) connected to the memory cell transistors MT to be subjected to the read operation from the voltage supply circuit 43 via the row decoders 130 and 230. The read pass voltage VPASS_READ is applied to the other word lines WL (unselected word lines WLusel).

While the voltages applied to the selected select gate line SGDsel and the select gate line SGS are being maintained, for example, the voltage Vss is applied to the unselected select gate line SGDusel from the voltage supply circuit 43 via the row decoders 130 and 230. Consequently, the selection transistors ST1 included in the selected string unit SU remains on, but the selection transistors ST1 included in the unselected string units SU are turned off. Note that both in the case of selected string units SU and unselected string units SU, the selection transistors ST2 included in the selected block BLK are turned on.

Consequently, since at least the selection transistors ST1 are turned off, the NAND strings NS included in the unselected string units SU do not form a current path. On the other hand, the NAND strings NS included in the selected string units SU either form or do not form a current path depending on a relationship between the read voltage VCGRV applied to the selected word line WLsel and the threshold voltages of the memory cell transistors MT.

The sense amplifiers 120 and 220 apply a voltage to the bit line BL connected with the selected NAND strings NS. In this state, the sense amplifiers 120 and 220 read data based on the value of the current flowing through the bit line BL. Specifically, it is determined whether the threshold voltage of the memory cell transistor MT to be subjected to a read operation is higher than the read voltage applied to the memory cell transistor MT. Note that the data read may be performed based not on the value of the current flowing through the bit line BL, but on the time variation of the potential of the bit line BL. In the latter case, the bit line BL is precharged to a predetermined voltage.

The verify operation described earlier is performed in a manner similar to the read operation described above. In the verify operation, a verify voltage such as VfyA is applied to the word line WL connected to the memory cell transistor MT to be verified from the voltage supply circuit 43 via the row decoders 130 and 230.

Note that the operation of applying a 5-V voltage to the unselected select gate line SGDusel and applying the read pass voltage VPASS_READ to the selected word line WLsel in an early stage of a read operation (verify operation) may be omitted.

### 1.8 Flow of Write Operation Into Semiconductor Storage Device

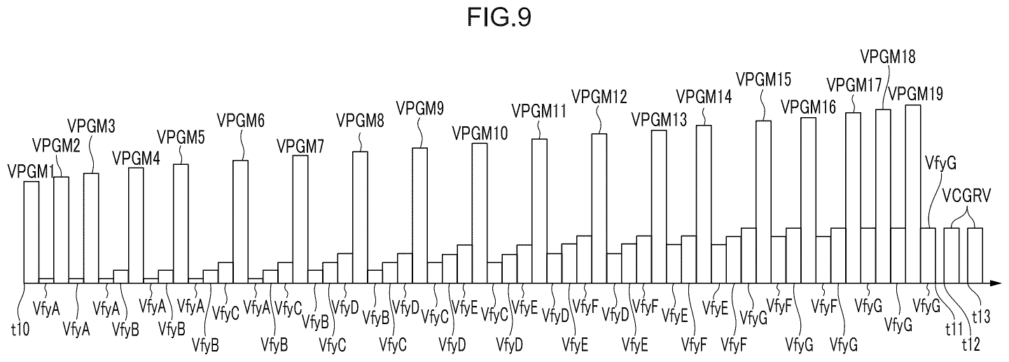

Next, a specific flow in an overall write operation will be described. In the write operation, the program operation and verify operation such as described above are repeated until it is confirmed that data has been written properly. FIG. 9 shows an example in which a combination of the program operation and verify operation is repeated 19 times, thereby writing data. Hereinafter, a set of operations repeated in this way will also be referred to as a “loop.”

FIG. 9 shows an example of changes in the potential of the selected word line WLsel during a write operation. As shown in FIG. 9, the loop is repeated up to 19 times. Note that “VPGM1” shown in FIG. 9 is VPGM applied to the selected word line WLsel in the first loop. “VPGM2” is VPGM applied to the selected word line WLsel in the second loop. Similarly, VPGMs applied to the selected word line WLsel in subsequent loops are denoted as “VPGM3,” “VPGM4,” . . . “VPGM19” in FIG. 9. As shown in FIG. 9, each time the loop is repeated, the value of VPGM is increased one by one.

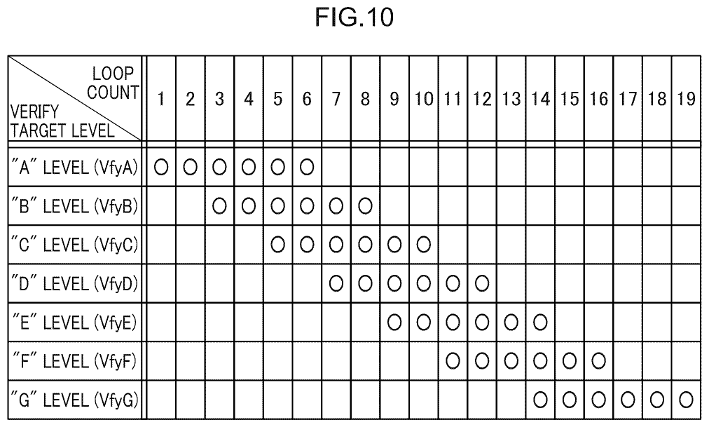

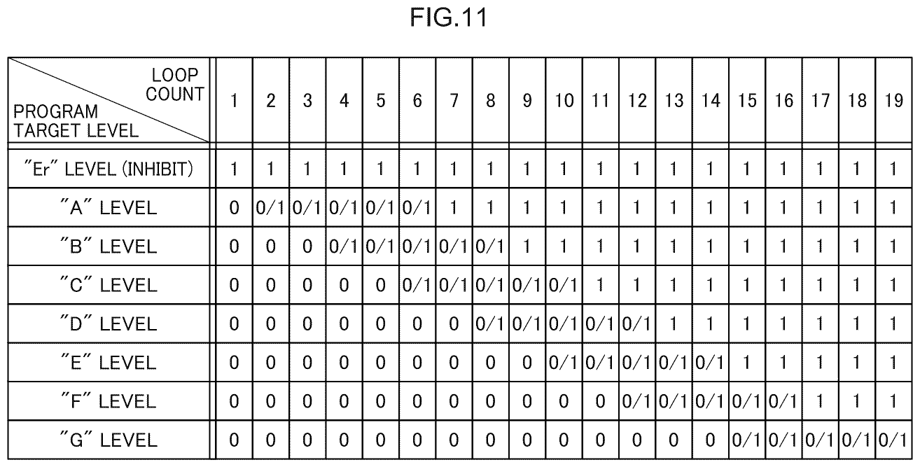

FIG. 10 shows a target level of the verify operation performed in each loop. FIG. 11 shows a target level of the program operation performed in each loop. Note that “1” shown in FIG. 11 means that the write operation is not performed at the given level while “0” means that the write operation is performed at the given level. On the other hand, “0/1” means that the write operation is performed at the given level as a rule but not performed if verification has been passed in the previous write operation.

As shown in FIGS. 9, 10 and 11, in the first loop in the above examples, VPGM1 is applied to the selected word line WLsel in the first loop in the program operation and then the verify operation is performed only at the “A” level. That is, during the verify operation, the verify voltage VfyA is applied to the selected word line WLsel, but the verify voltages VfyB to VfyG are not applied.

Note that all the memory cell transistors MT, the threshold voltages of which will eventually become the “A” level or above in the first loop are targeted for programming. On the other hand, the memory cell transistors MT, the threshold voltages of which will eventually become the “A” level in the first loop are targeted for verification. The memory cell transistors MT, the threshold voltages of which will eventually become the “B” level or above are excluded from “A” level verification.

In the second loop, after VPGM2 is applied to the selected word line WLsel, a program operation and a verify operation similar to those performed in the first loop are carried out. However, of the memory cell transistors MT, the threshold voltages of which will eventually become the “A” level, those that have passed the “A” level verification in the first loop are exempted from the program operation and the verify operation in the second loop. That is, in the second loop, the memory cell transistors MT, the threshold voltages of which will eventually become the “B” level or above and the memory cell transistors MT that have failed verification in the previous loop are targeted for the program operation.

In the third loop, after VPGM3 is applied to the selected word line WLsel and the program operation is performed, the verify operation is performed at the “A” level and “B” level. That is, during the verify operation, the verify voltages VfyA and VfyB are applied in sequence to the selected word line WLsel, but the verify voltages VfyC to VfyG are not applied.

Note that the memory cell transistors MT targeted for programming in the third loop are: all the memory cell transistors MT, the threshold voltages of which will eventually become the “B” level or above, and the memory cell transistors MT that have failed verification in the previous loops. The memory cell transistors MT targeted for “A” level verification in the third loop are memory cell transistors MT whose threshold voltages will eventually become the “A” level but which have failed verification in the previous loops. The memory cell transistors MT targeted for “B” level verification in the third loop are the memory cell transistors MT, the threshold voltages of which will eventually become the “B” level.

In the fourth loop, after VPGM4 is applied to the selected word line WLsel, a program operation and a verify operation similar to those performed in the third loop are carried out. However, of the memory cell transistors MT, the threshold voltages of which will eventually become the “A” level, those that have passed the “A” level verification in the third loop are exempted from the program operation and the verify operation in the second loop. Similarly, the memory cell transistors MT that have passed the “B” level verification in the third loop are exempted from the program operation and the verify operation in the fourth loop. That is, in the fourth loop, the memory cell transistors MT, the threshold voltages of which will eventually become the “C” level or above and the memory cell transistors MT that have failed verification in the previous loop are targeted for the program operation.

Similarly, in subsequent loops, after the program operation, verify operations at predetermined levels such as shown in FIG. 7 are carried out. The memory cell transistors MT, the threshold voltages of which have reached final target levels are exempted from the program operation and the verify operation in the subsequent loops.

As the loop is repeated, the memory cell transistors MT, the threshold voltages of which have reached final target levels increase, and consequently the memory cell transistors MT exempted from the program operation and the verify operation increase gradually. This point is shown in the fact that the number of levels marked “1” increases and the number of levels marked “0” decreases with the number of loops.

Note that in the example shown in FIG. 10, the verify operation targeted for the “A” level completes in the sixth loop. This is because it is known, for example, from the characteristics of the memory cell array 110 obtained in advance, that a data write at the “A” level is almost completed by going through a total of six loops. Similarly, in the example shown in FIG. 10, the verify operation targeted for the “B” level is completed in the eighth loop. This is because it is known that a data write at the “B” level is almost completed by going through a total of six loops from the third to eighth loops.

### 1.9 Schematic Configurations of Plane Control Circuit and Row Decoders

Next, respective schematic configurations of the plane control circuit 44 and row decoders 130 and 230 will be described. Note that the row decoders 130 and 230 are identical in configuration, and thus the configuration of only the row decoder 130 will be described below, and description of the row decoder 230 will be omitted.

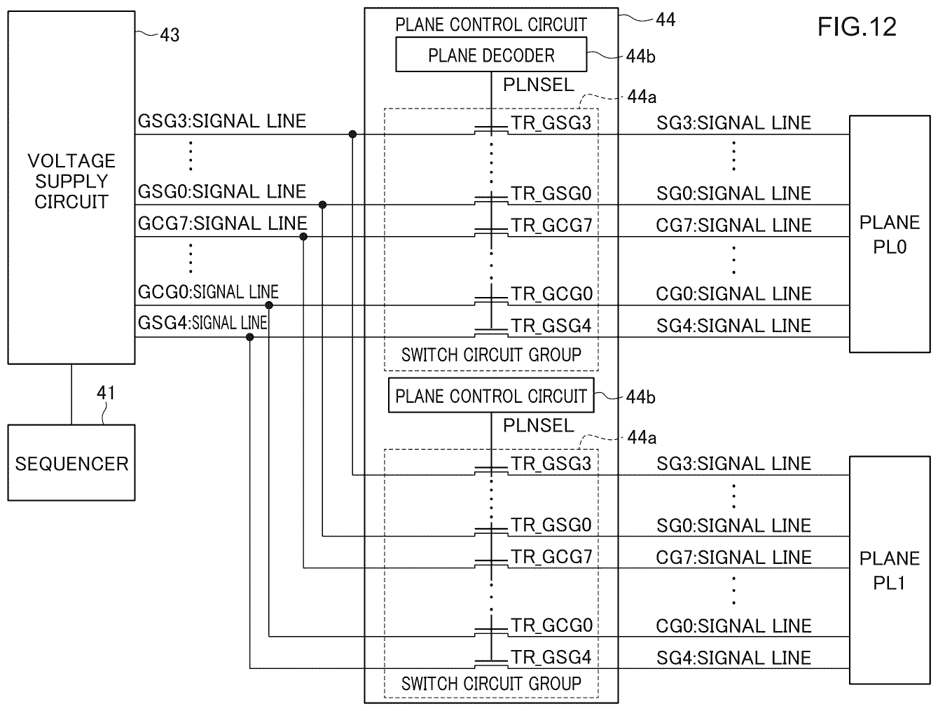

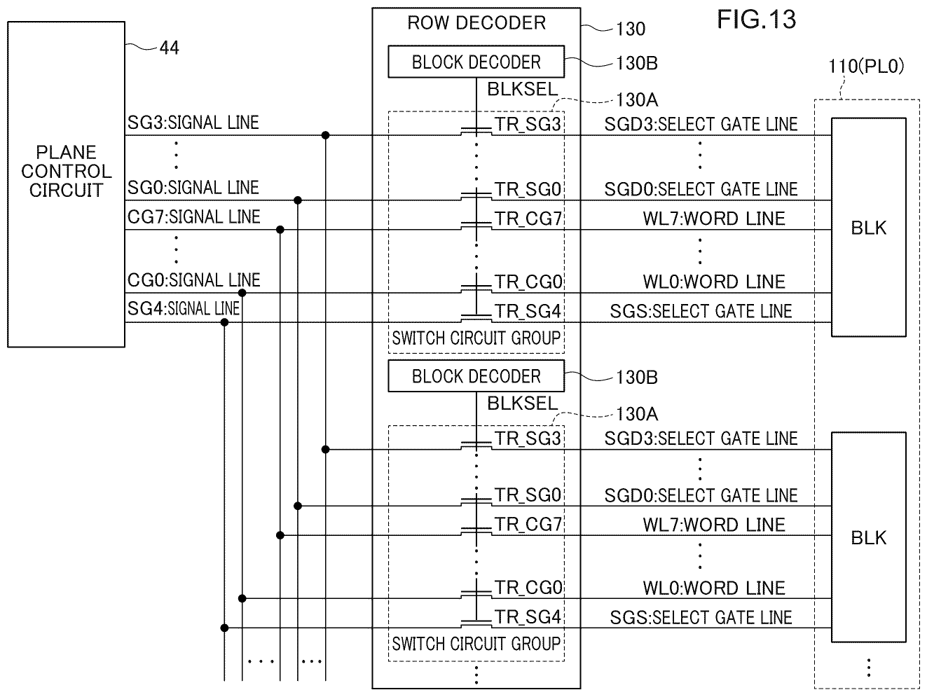

FIG. 12 is a block diagram showing a schematic configuration of the plane control circuit 44. FIG. 13 is a block diagram showing a schematic configuration of the row decoder 130.

Under the control of the sequencer 41, the voltage supply circuit 43 shown in FIG. 12 generates various types of voltages including the voltages necessary for write operations, read operations, erase operations, and other operations on the memory cell transistors MT. The voltage supply circuit 43 selects appropriate voltages from the generated voltages and supplies the selected voltages to signal lines GSG0 to GSG4 and GCG0 to GCG7, respectively.

The signal lines GSG0 to GSG4 and GCG0 to GCG7 bifurcate in an intermediate part between the voltage supply circuit 43 and the plane control circuit 44. One part of the bifurcated signal lines GSG0 to GSG4 and GCG0 to GCG7 are connected, respectively, to signal lines SG0 to SG4 and CG0 to CG7 corresponding to the plane PL0 via the plane control circuit 44. The other part of the bifurcated signal lines GSG0 to GSG4 and GCG0 to GCG7 are connected, respectively, to signal lines SG0 to SG4 and CG0 to CG7 corresponding to the plane PL1 via the plane control circuit 44.

As shown in FIG. 13, the signal lines SG0 to SG4 and CG0 to CG7 extending from the plane control circuit 44 to the plane PL0 branch into multiple parts in an intermediate part between the plane control circuit 44 and the row decoder 130. The branched signal lines SG0 to SG4 and CG0 to CG7 are connected to the select gate lines SGD0 to SGD3, the select gate line SGS, and the word lines WL0 to WL7 on each block BLK of the plane PL0 via the row decoder 130. This similarly applies to the plane PL1.

In this way, the signal lines GSG0 to GSG4 and GCG0 to GCG7 function as global signal lines for the planes PL0 and PL1 and are connected to the planes PL0 and PL1 via the plane control circuit 44. Hereinafter, the signal lines GSG0 to GSG4 and GCG0 to GCG7 will also be referred to as “first global signal lines GSG0 to GSG4 and GCG0 to GCG7.”

The signal lines SG0 to SG3 function as global drain-side selected gate lines and are connected to the select gate lines SGD0 to SGD3 on the blocks BLK of the planes PL0 and PL1 via the row decoders 130 and 230. The signal lines CG0 to CG7 function as global word lines and are connected to the word lines WL0 to WL7 on each block BLK of the planes PL0 and PL1 via the row decoders 130 and 230. The signal line SG4 functions as a global source-side selected gate line and is connected to the select gate line SGS on each block BLK of the planes PL0 and PL1 via the row decoders 130 and 230. Hereinafter, the signal lines SG0 to SG4 and CG0 to CG7 will also be referred to as “second global signal lines SG0 to SG4 and CG0 to CG7.”

As shown in FIG. 12, the plane control circuit 44 includes a plurality of switch circuit groups 44a corresponding to respective planes PL0 and PL1 and a plurality of plane decoders 44b provided, respectively, for the plurality of switch circuit groups 44a.

Each of the switch circuit groups 44a includes a plurality of transistors TR_GSG0 to TR_GSG4 provided between the first global signal lines GSG0 to GSG4 and the second global signal lines SG0 to SG4 and connected with each other. Each of the switch circuit groups 44a also includes a plurality of transistors TR_GCG0 to TR_GCG7 provided between the first global signal lines GCG0 to GCG7 and the second global signal lines CG0 to CG7. The transistors TR_GSG0 to TR_GSG4 and TR_GCG0 to TR_GCG7 are high-voltage transistors.

On instructions from the sequencer 41, the plane decoders 44b supply a logic high plane selection signal PLNSEL to respective gates of the transistors TR_GSG0 to TR_GSG4 and TR_GCG0 to TR_GCG7. In the switch circuit groups 44a being supplied with the logic high plane selection signal PLNSEL from the plane decoders 44b, each of the transistors TR_GSG0 to TR_GSG4 and TR_GCG0 to TR_GCG7 is turned on and starts conducting. Therefore, voltages generated by the voltage supply circuit 43 are supplied to the second global signal lines SG0 to SG4 and CG0 to CG7 via the first global signal lines GSG0 to GSG4 and GCG0 to GCG7. Accordingly, the plane corresponding to the plane decoder 44b that is being supplied with the logic high plane selection signal PLNSEL is enabled.

On the other hand, on instructions from the sequencer 41, the plane decoders 44b supply a logic low plane selection signal PLNSEL to respective gates of the transistors TR_GSG0 to TR_GSG4 and TR_GCG0 to TR_GCG7. In the switch circuit groups 44a being supplied with the logic low plane selection signal PLNSEL from the plane decoders 44b, each of the transistors TR_GSG0 to TR_GSG4 and TR_GCG0 to TR_GCG7 is turned off and goes out of conduction. Therefore, voltages generated by the voltage supply circuit 43 are not supplied to the second global signal lines SG0 to SG4 and CG0 to CG7 via the first global signal lines GSG0 to GSG4 and GCG0 to GCG7. Accordingly, the plane corresponding to the plane decoder 44b being supplied with the logic low plane selection signal PLNSEL is disabled.

In this way, the respective operating states of the planes PL0 and PL1 can be switched by the plane selection signal PLNSEL output from the plane decoders 44b. For example, when the plane decoders 44b for the planes PL0 and PL1 both output a logic high plane selection signal PLNSEL, the planes PL0 and PL1 are both enabled. In contrast, for example, if the plane decoder 44b for the plane PL0 outputs a logic high plane selection signal PLNSEL while the plane decoder 44b for the plane PL1 outputs a logic low plane selection signal PLNSEL, the plane PL0 is enabled, but the plane PL1 is disabled.

As shown in FIG. 13, the row decoder 130 includes a plurality of switch circuit groups 130a corresponding to respective blocks BLK of the plane PL0, and a plurality of block decoders 130b provided for the plurality of switch circuit groups 130a, respectively.

Each of the switch circuit groups 130a include a plurality of transistors TR_SG0 to TR_SG4 provided between the second global signal lines SG0 to SG4 and select gate lines SGD0 to SGD4 and connected with each other. Each of the switch circuit groups 130a also includes a plurality of transistors TR_CG0 to TR_CG7 provided between the second global signal lines CG0 to CG7 and the word lines WL0 to WL7. The transistors TR_SG0 to TR_SG4 and TR_CG0 to TR_CG7 are all high-voltage transistors.

When specified by row address, each of the block decoders 130b supplies a logic high block selection signal BLKSEL to the switch circuit group 130a. Consequently, the logic high block selection signal BLKSEL is supplied to respective gates of the transistors TR_SG0 to TR_SG4 and TR_CG0 to TR_CG7 included in the switch circuit group 130a, and the transistors TR_SG0 to TR_SG4 and TR_CG0 to TR_CG7 are turned on and start conducting. Therefore, voltages supplied from the first global signal lines GSG0 to GSG4 and GCG0 to GCG7 to the second global signal lines SG0 to SG4 and CG0 to CG7, i.e., the voltages generated by the voltage supply circuit 43, are supplied to the select gate lines SGD0 to SGD3, select gate line SGS, and word lines WL0 to WL7 included in the block BLK to be operated.

On the other hand, when not specified by row address, each of the block decoders 130b supplies a logic low block selection signal to the switch circuit group 130a. Consequently, the logic low block selection signal BLKSEL is supplied to respective gates of the transistors TR_SG0 to TR_SG4 and TR_CG0 to TR_CG7 included in the switch circuit group 130a, and the transistors TR_SG0 to TR_SG4 and TR_CG0 to TR_CG7 are turned off and go out of conduction. Therefore, voltages supplied from the first global signal lines GSG0 to GSG4 and GCG0 to GCG7 to the second global signal lines SG0 to SG4 and CG0 to CG7, i.e., the voltages generated by the voltage supply circuit 43, are not supplied to the select gate lines SGD0 to SGD3, select gate line SGS, and word lines WL0 to WL7 included in the block BLK not to be operated.

Thus, to perform write operations, for example, into the plane PL0 and the plane PL1, in the plane control circuit 44, the plane decoder 44b for the plane PL0 and the plane decoder 44b for the plane PL1 output a logic high plane selection signal PLNSEL. Consequently, in the plane control circuit 44, the transistors TR_GSG0 to TR_GSG4 and TR_GCG0 to TR_GCG7 corresponding to each of the planes PL0 and PL1 are turned on. Therefore, the voltages generated by the voltage supply circuit 43 are supplied to the second global signal lines SG0 to SG4 and CG0 to CG7 via the first global signal lines GSG0 to GSG4 and GCG0 to GCG7.

Besides, to perform write operations simultaneously, for example, into a predetermined page in the block BLK(0) of the plane PL0 and a predetermined page in the block BLK(2) of the plane PL1, the respective row decoders 130 and 230 for the planes PL0 and PL1 come into operation.

Specifically, in the row decoder 130 for the plane PL0, the block decoder 130b for the selected block BLK(0) outputs a logic high block selection signal BLKSEL. Consequently, the transistors TR_SG0 to TR_SG4 and TR_CG0 to TR_CG7 for the respective selected block BLK(0) are turned on, and thus the voltages generated by the voltage supply circuit 43 are supplied to the select gate lines SGD0 to SGD3, word lines WL0 to WL7, and select gate line SGS on the selected block BLK(0) of the plane PL0 via the first global signal lines GSG0 to GSG4 and GCG0 to GCG7 and the second global signal lines SG0 to SG4 and CG0 to CG7. Consequently, a program operation and a verify operation on a predetermined page are performed on the selected block BLK(0) of the plane PL0.

Furthermore, in the row decoder 130 for the plane PL0, the block decoders 130b for the respective unselected blocks BLK(2) to BLK(n−1) output a logic low block selection signal BLKSEL. Consequently, the transistors TR_SG0 to TR_SG4 and TR_CG0 to TR_CG7 for the unselected blocks BLK(2) to BLK(n−1) are turned off and thus the voltages generated by the voltage supply circuit 43 are not supplied to the respective select gate lines SGD0 to SGD3, word lines WL0 to WL7, and select gate line SGS on the unselected blocks BLK(2) to BLK(n−1) of the plane PL0. Therefore, a program operation and a verify operation are not performed on the unselected blocks BLK(2) to BLK(n−1) of the plane PL0.

On the other hand, in the row decoder 130 for the plane PL1, the block decoder 130b for the selected block BLK(2) outputs a logic high block selection signal BLKSEL. Besides, in the row decoder 130 for the plane PL1, the block decoders 130b for the respective unselected blocks BLK(0), BLK(1), and BLK(3) to BLK(n−1) output a logic low block selection signal BLKSEL. Consequently, a program operation and a verify operation on a predetermined page are performed on the selected block BLK(2) of the plane PL1 while no program operation or verify operation is performed on the unselected blocks BLK(0), BLK(1), and BLK(3) to BLK(n−1) of the plane PL1.

Incidentally, with the semiconductor storage device 2 such as described above, due to stress cycles and the like resulting from its use, the word lines WL of the memory cell arrays 110 and 210 may cause electrical leakage. For example, if a word line WL4 included in the block BLK(0) of the plane PL0 is electrically short-circuited with a word line WL3, the word line WL4 may cause electrical leakage. In such a case, if the voltage of the word line WL4 is affected by the voltage of the word line WL3, abnormality may be detected on the block BLK(0).

For example, in performing a program operation of a memory cell transistor MT4 in the block BLK(0), the word line WL4 becomes a selected word line WLsel and the word line WL3 becomes an unselected word line WLusel. In so doing, as shown in FIG. 7, the program voltage VPGM is applied to the selected word line WL4 and the program pass voltage VPASS_PGM is applied to the unselected word line WL3. In such a case, if the selected word line WL4 and the unselected word line WL3 are electrically short-circuited, the voltage of the selected word line WL4 will be pulled by the voltage of the unselected word line WL3, thereby making the voltage of the unselected word line WL3 lower than the program voltage VPGM. Therefore, the program operation may not be performed appropriately. Similarly, during a verify operation, the voltage of the selected word line WL4 will be pulled by the voltage of the unselected word line WL3, which may result in the verify operation not being performed appropriately. If a program operation or a verify operation is not performed appropriately such as described above, the number of fail decisions increases in the verify operation, causing the sequencer 41 to determine that a write into the block BLK(0) of the plane PL0 has failed. In so doing, the sequencer 41 writes information into the status register 42c, the information indicating that a write operation into the block BLK(0) of the plane PL0 has failed. Based on the information written into the status register 42c, information that the block BLK(0) of the plane PL0 is a bad block is written into the ROM block of the memory cell array 210, thereby causing the block BLK(0) to be excluded from subsequent operations.

On the other hand, with the semiconductor storage device 2, a write operation into the block BLK(0) of the plane PL0 and a write operation into the block BLK(2) of the plane PL1 may be performed simultaneously. In such a case, due to electrical leakage from the word line WL4 in the block BLK(0) of the plane PL0, the block BLK(2) of another plane PL1 may be registered as a bad block even if the block BLK(2) is normal, specifically as follows.

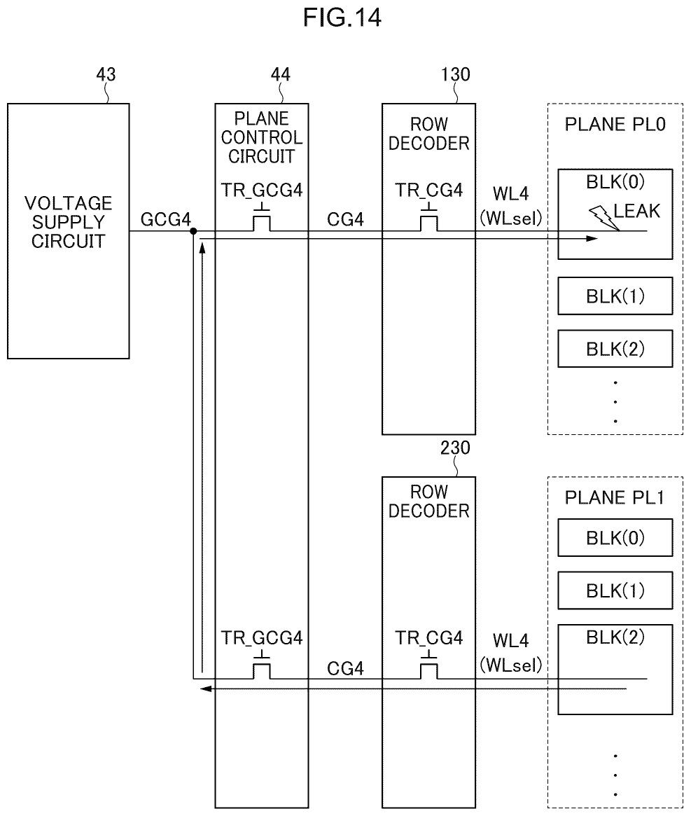

FIG. 14 schematically shows a circuit configuration of the semiconductor storage device 2. As shown in FIG. 14, with the semiconductor storage device 2, when a write operation into the block BLK(0) of the plane PL0 and a write operation into the block BLK(2) of the plane PL1 are being performed simultaneously, the word line WL4 in the block BLK(0) of the plane PL0 may get electrically connected with the word line WL4 in the block BLK(2) of the plane PL1 via the second global signal line CG4 and first global signal line GCG4 for the plane PL0 and via the second global signal line CG4 for the plane PL1. Therefore, through paths indicated by arrows in FIG. 14, the voltage of the word line WL4 in the block BLK(2) of the plane PL1 is also affected by the electrical leakage from the word line WL4 in the block BLK(0) of the plane PL0. Consequently, a program operation or verify operation of the memory cell transistor MT4 in the block BLK(2) of the plane PL1 is not performed appropriately, which may result in a fail decision in the verify operation. Even if no fail decision is produced in the verify operation of the memory cell transistor MT4 in the block BLK(2) of the plane PL1, a fail decision may be made subsequently during a read operation of the memory cell transistor MT4. In such a case, the block BLK(2) of the plane PL1 may be registered as a bad block in the ROM block of the memory cell array 210 even if the block BLK(2) is normal.

Thus, with the semiconductor storage device 2, if a word line WL on any one of the planes PL0 and PL1 causes electrical leakage, not only blocks BLK on either one of the planes PL0 and PL1 will be determined to be a bad block as a result, but also blocks BLK on the other of the planes PL0 and PL1 going through a write operation at the same time might be determined together collaterally as being a bad block. The block BLK determined together collaterally as being a bad block is actually a normal block, and thus if the block can be used as a good block, block usage efficiency of the semiconductor storage device 2 can be improved.

Thus, the semiconductor storage device 2 according to the present embodiment detects a killer block suffering electrical leakage and a victim block likely to be determined together collaterally as being a bad block, reregisters the detected block as a good block, and thereby makes it possible to reuse any block likely to be determined together collaterally as being a bad block.

### 1.10 Configuration of Determination Circuit

Next, a configuration of a determination circuit capable of determining a killer block and victim blocks will be described.

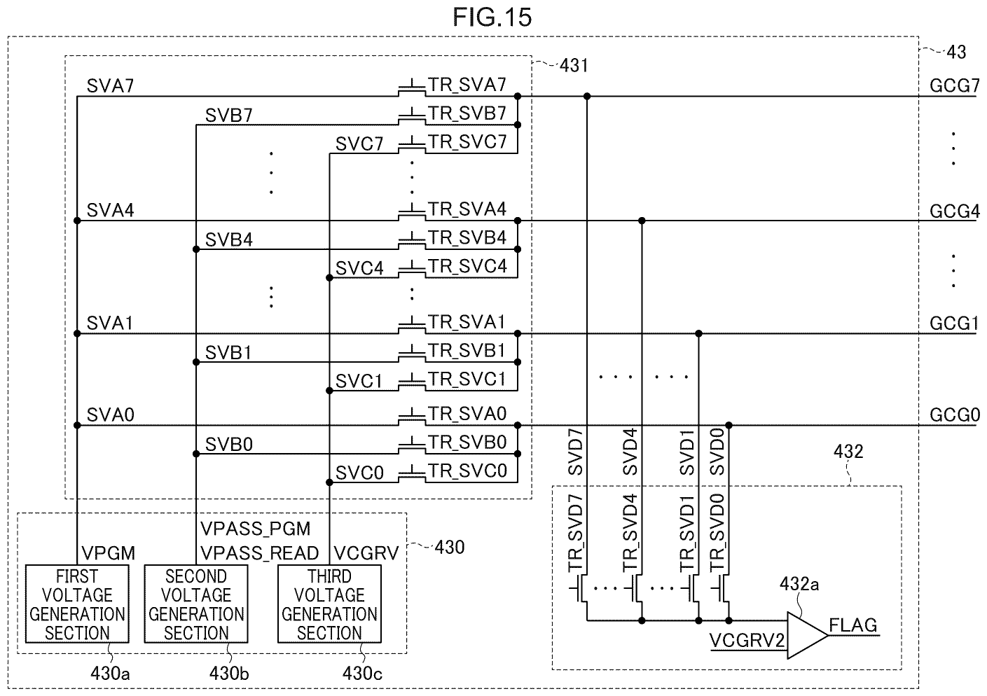

FIG. 15 is a block diagram showing an internal configuration of the voltage supply circuit 43. As shown in FIG. 15, the voltage supply circuit 43 includes a voltage generation circuit 430, a multiplexer 431, and a determination circuit 432. Note that in FIG. 15, only a configuration used to apply a voltage to the first global signal lines GCG0 to GCG7 in the voltage supply circuit 43 is illustrated, and illustration of a configuration used to apply a voltage to the first global signal lines GSG0 to GSG4 is omitted.

The voltage generation circuit 430 includes a first voltage generation section 430a, a second voltage generation section 430b, and a third voltage generation section 430c. The first voltage generation section 430a generates a program voltage VPGM applied to the selected word line WLsel during a write operation. The second voltage generation section 430b generates the program pass voltage VPASS_PGM applied to the unselected word line WLusel during a write operation and the voltage VPASS_READ applied to the unselected word line WLusel during a read operation. The third voltage generation section 430c generates the read voltage VCGRV applied to the selected word line WLsel during a read operation.

In the multiplexer 431, the first voltage generation section 430a is connected to the first global signal lines GCG0 to GCG7 via a plurality of signal lines SVA0 to SVA7. Also, the second voltage generation section 430b is connected to the first global signal lines GCG0 to GCG7 via a plurality of signal lines SVB0 to SVB7. Furthermore, the third voltage generation section 430c is connected to the first global signal lines GCG0 to GCG7 via a plurality of signal lines SVC0 to SVC7. The multiplexer 431 includes transistors TR_SVA0 to TR_SVA7, TR_SVB0 to TR_SVB7, and TR_SVC0 to TR_SVC7. The transistors TR_SVA0 to TR_SVA7 are provided at midpoints of the plurality of signal lines SVA0 to SVA7, respectively. The transistors TR_SVB0 to TR_SVB7 are provided at midpoints of the plurality of signal lines SVB0 to SVB7, respectively. The transistors TR_SVC0 to TR_SVC7 are provided at midpoints of the plurality of signal lines TR_SVC0 to TR_SVC7, respectively. Respective operations of the transistors TR_SVA0 to TR_SVA7, TR_SVB0 to TR_SVB7, and TR_SVC0 to TR_SVC7 are controlled by the sequencer 41.

By turning on and off each of the transistors TR_SVA0 to TR_SVA7, TR_SVB0 to TR_SVB7, and TR_SVC0 to TR_SVC7, the multiplexer 431 selectively applies the voltages generated by the respective voltage generation sections 430a, 430b, and 430c to the first global signal lines GCG0 to GCG7.

For example, during a write operation, if the word line WL4 is a selected word line WLsel, the multiplexer 431 turns on the transistor TR_SVA4 and turns off the transistors TR_SVB4 and TR_SVC4 and thereby applies the program voltage VPGM to the first global signal line GCG4 connected to the selected word line WL4. Besides, the multiplexer 431 turns on the transistors TR_SVB0 to TR_SVB3 and TR_SVB5 to TR_SVB7 and turns off the transistors TR_SVA1 to TR_SVA3, TR_SVA5 to TR_SVA7, TR_SVC1 to TR_SVC3, and TR_SVC5 to TR_SVC7 and thereby applies the program pass voltage VPASS_PGM to the other first global signal lines GCG0 to GCG3 and GCG5 to GCG7 connected to the unselected word lines WL0 to WL3 and WL5 to WL7.

On the other hand, during a read operation, if the word line WL4 is a selected word line WLsel, the multiplexer 431 turns on the transistor TR_SVC4 and turns off the transistors TR_SVA4 and TR_SVB4 and thereby applies the read voltage VCGRV to the first global signal line GCG4 connected to the selected word line WL4. Besides, the multiplexer 431 turns on the transistors TR_SVB0 to TR_SVB3 and TR_SVB5 to TR_SVB7 and turns off the transistors TR_SVA0 to TR_SVA3, TR_SVA5 to TR_SVA7, TR_SVC0 to TR_SVC3, and TR_SVC5 to TR_SVC7 and thereby applies the read pass voltage VPASS_READ to the other first global signal lines GCG0 to GCG3 and GCG5 to GCG7 connected to the unselected word lines WL0 to WL3 and WL5 to WL7.

The determination circuit 432 includes a comparison circuit 432a and transistors TR_SVD0 to TR_SVD7.

A non-inverting input terminal of the comparison circuit 432a is connected to the first global signal lines GCG0 to GCG7 via signal lines SVD0 to SVD7. The transistors TR_SVD0 to TR_SVD7 are provided in intermediate parts of the respective signal lines SVD0 to SVD7. Respective operations of the transistors TR_SVD0 to TR_SVD7 are controlled by the sequencer 41. When write operations, read operations, erase operations, and other operations are being performed, the transistors TR_SVD0 to TR_SVD7 remain off. A reference voltage VCGRV2 is being applied to an inverting input terminal of the comparison circuit 432a. The reference voltage VCGRV2 is generated by the voltage generation circuit 430 by stepping down the read voltage VCGRV, and thus is equal to or lower than the read voltage VCGRV. Respective operations of the transistors TR_SVD0 to TR_SVD7 are controlled by the sequencer 41.

The comparison circuit 432a compares a voltage being applied to any of the first global signal lines GCG0 to GCG7 with the reference voltage VCGRV2, and thereby outputs an output signal FLAG according to comparison results. For example, when it is desired to determine the voltage being applied to the first global signal line GCG0, the sequencer 41 turns on the transistor TR_SVD0 and turns off the other transistors TR_SVD1 to TR_SVD7. Consequently, the voltage of the first global signal line GCG0 is applied to the non-inverting input terminal of the comparison circuit 432a. In so doing, if the voltage of the first global signal line GCG0 is higher than the reference voltage VCGRV2, the comparison circuit 432a outputs a logic low signal. On the other hand, if the voltage of the first global signal line GCG0 is equal to or lower than the reference voltage VCGRV2, the comparison circuit 432a outputs a logic high signal.

### 1.11 Operation Examples of Memory System

Next, operation examples of the memory system 3 according to the present embodiment will be described.

First, a method for detecting a killer block and victim blocks using the determination circuit 432 shown in FIG. 15 will be described.

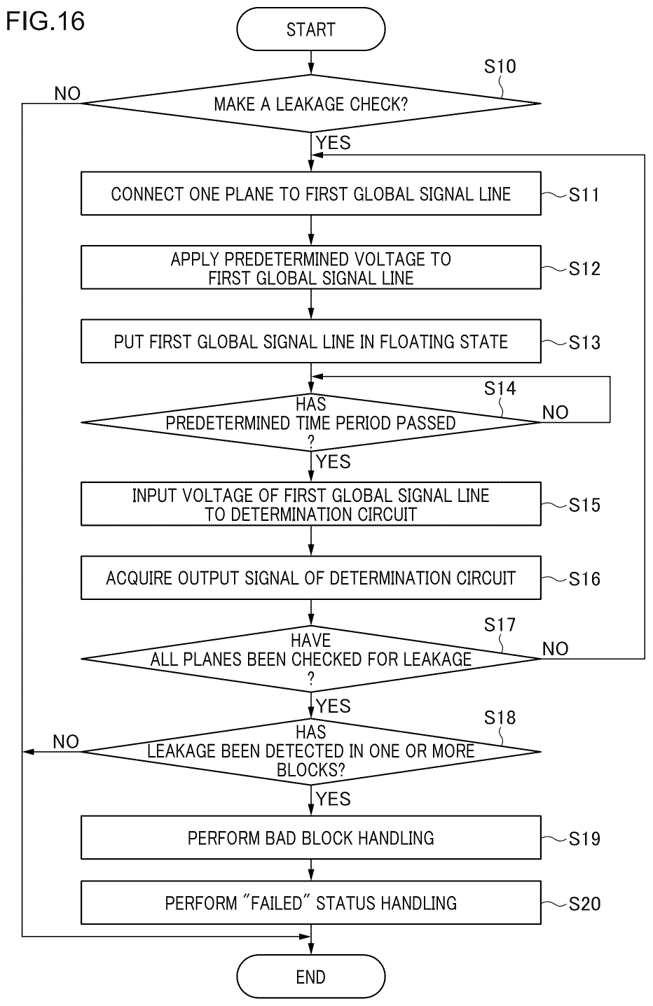

FIG. 16 shows an example of procedures for a detection process performed by the sequencer 41 to detect a killer block and victim blocks. Note that the detection method is described below by taking as an example a case in which write operations are performed simultaneously in the block BLK(0) of the plane PL0 and the block BLK(2) of the plane PL1.

As shown in FIG. 16, first, the sequencer 41 determines whether it is time to make a leakage check (step S10). A time point used as the time to make a leakage check is, for example, the time at which a data write into a predetermined memory cell transistor is completed in each of the block BLK(0) on the plane PL0 and the block BLK(2) on the plane PL1. Specifically, for example, if a data write into a predetermined memory cell transistor is started at time t10 in FIG. 9 and then a verify operation using the verify voltage VfyG is completed at time t11, the sequencer 41 determines at time t11 that it is time to make a leakage check. Note that description will be given below by taking as an example a case in which the predetermined memory cell transistor is MT4, i.e., the word line WL4 is a selected word line WLsel.

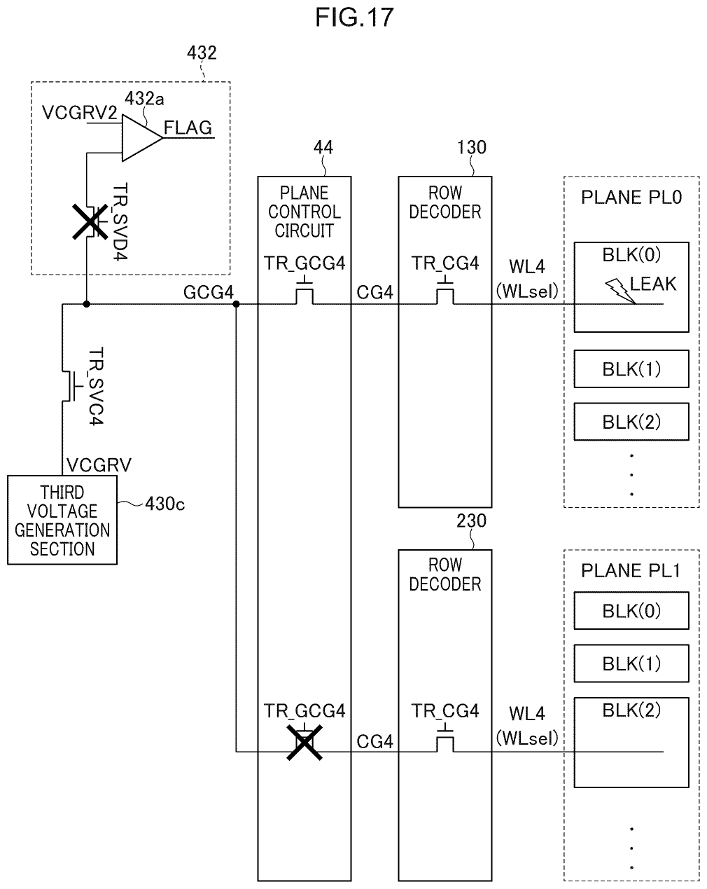

If it is determined that it is time to make a leakage check (step S10: YES), the sequencer 41 connects one of the planes PL0 and PL1 to the first global signal line CGC4 (step S11). First, the sequencer 41 connects, for example, the plane PL0 with the first global signal line CGC4 and breaks the connection between the plane PL1 and the first global signal line CGC4. Specifically, the sequencer 41 causes the plane control circuit 44 shown in FIG. 12 to output a logic high plane selection signal PLNSEL from the plane decoder 44b for the plane PL0 and output a logic low plane selection signal PLNSEL from the plane decoder 44b for the plane PL1. Consequently, the transistors TR_GCG0 to TR_GCG7 corresponding to the plane PL0 are turned on, connecting the plane PL0 with the first global signal line GCG4. On the other hand, the transistors TR_GCG0 to TR_GCG7 corresponding to the plane PL1 are turned off, breaking the connection between the plane PL1 and the first global signal line GCG4. As a result, as shown in FIG. 17, the selected word line WL4 of the plane PL0 is connected to the first global signal line GCG4 and the selected word line WL4 of the plane PL1 becomes unconnected to the first global signal line GCG4.

Next, the sequencer 41 applies the voltage VCGRV generated by the third voltage generation section 430c to the first global signal line GCG4 corresponding to the selected word line WL4 of the plane PL0 (step S12). Specifically, in the voltage supply circuit 43 shown in FIG. 15, to apply the voltage VCGRV to the first global signal line GCG4 corresponding to the selected word line WL4, the sequencer 41 turns on the transistor TR_SVC4 and turns off the transistors TR_SVA4 and TR_SVB4. Consequently, as shown in FIG. 17, the voltage VCGRV generated by the third voltage generation section 430c is applied to the selected word line WL4 in the block BLK(0) of the plane PL0 via the first global signal line GCG4 and the second global signal line CG4 for the plane PL0. In FIG. 9, the time at which the voltage VCGRV is applied to the selected word line WL4 in the block BLK(0) of the plane PL0 is denoted by t12.

Note that the voltage Vss is applied to the other first global signal lines GCG0 to GCG3 and GCG5 to GCG7 by the voltage supply circuit 43. Therefore, the voltage Vss is applied to the unselected word lines WL0 to WL3 and WL5 to WL7 in the block BLK(0) of the plane PL0.

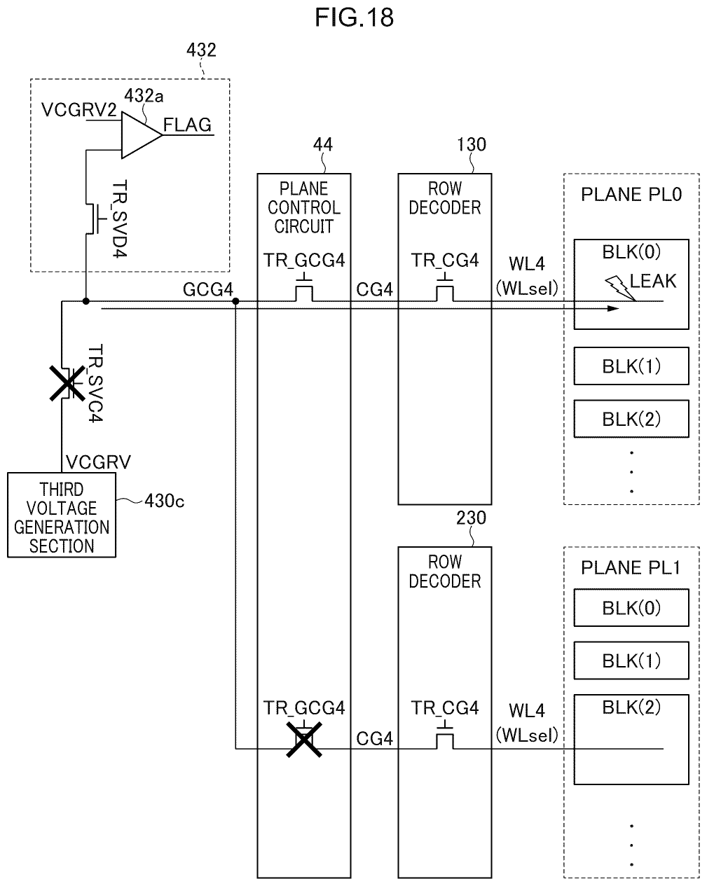

Next, as shown in FIG. 16, the sequencer 41 puts the first global signal line GCG4 corresponding to the selected word line WL4 of the plane PL0 in a floating state (step S13). Specifically, the sequencer 41 causes the plane control circuit 44 shown in FIG. 12 to output a logic low plane selection signal PLNSEL from the plane decoder 44b for the plane PL0. Consequently, the transistors TR_GCG0 to TR_GCG7 corresponding to the plane PL0 are switched from ON to OFF, putting the first global signal line GCG4 in a floating state as shown in FIG. 18.

Next, as shown in FIG. 16, the sequencer 41 determines whether a predetermined time period Ta has passed since placement of the first global signal line GCG4 in a floating state (step S14), and if the predetermined time period Ta has passed (step S14: YES), the sequencer 41 inputs the voltage of the first global signal line GCG4 to the determination circuit 432 shown in FIG. 15 (step S15). Specifically, the sequencer 41 turns on the transistor TR_SVD4 while keeping off the transistors TR_SVD0 to TR_SVD3 and TR_SVD5 to TR_SVD7 shown in FIG. 15. Consequently, the voltage of the first global signal line GCG4 is input to the non-inverting input terminal of the comparison circuit 432a of the determination circuit 432.

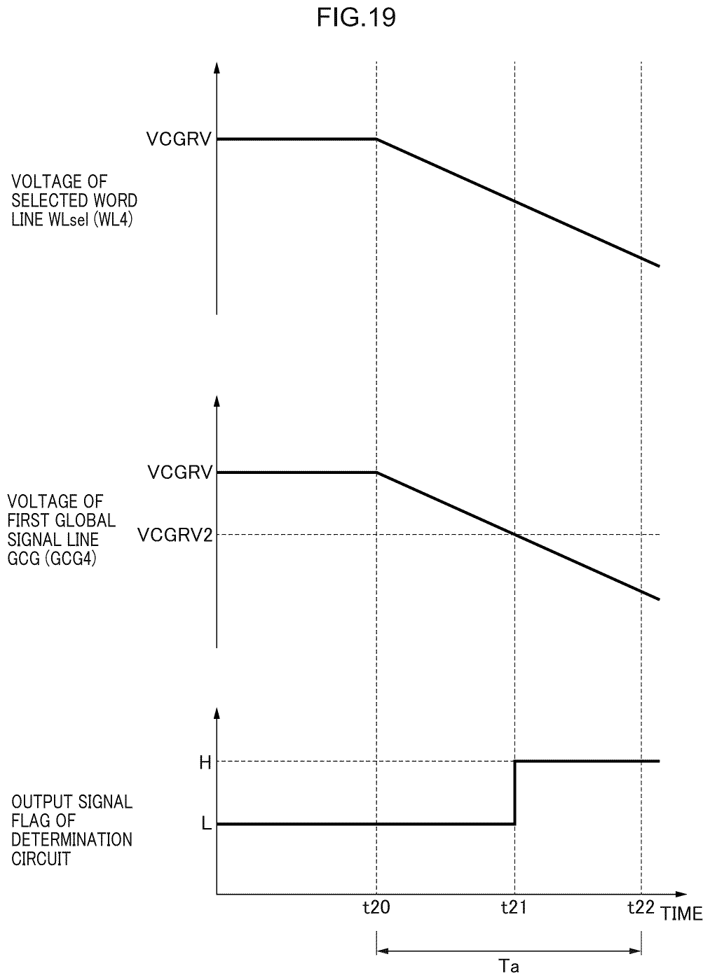

Next, as shown in FIG. 16, the sequencer 41 acquires the output signal FLAG of the determination circuit 432 shown in FIG. 15 (step S16). In so doing, as shown in FIG. 18, if there is leakage in the selected word line WL4 in the block BLK(0) of the plane PL0, e.g., if there is leakage between the selected word line WL4 and the unselected word line WL3, the voltage of the selected word line WL4 is discharged toward the unselected word line WL3 to which the voltage Vss is being applied. Therefore, as shown in the upper part of FIG. 19, after the first global signal line GCG4 enters a floating state at time t20, the voltage of the selected word line WL4 drops gradually from VCGRV. In so doing, the voltage of the first global signal line GCG4 drops as well along the paths indicated by arrows in FIG. 18 by being pulled by the voltage of the selected word line WL4. Therefore, as shown in the middle part of FIG. 19, the voltage of the first global signal line GCG4 also drops gradually from VCGRV after time t20. As a result, the voltage of the first global signal line GCG4 becomes lower than the reference voltage VCGRV2 at time t21, and thus as shown in the lower part of FIG. 19, the output signal FLAG of the comparison circuit 432a changes from logic low to logic high. Therefore, when the sequencer 41 acquires the output signal FLAG of the determination circuit 432 at time t22 after a lapse of the predetermined time period Ta from time t20, the output signal FLAG is logic high. The sequencer 41 stores correspondence between the acquired output signal FLAG and the block BLK(0) of the plane PL0 in a non-illustrated internal register in the sequencer 41.

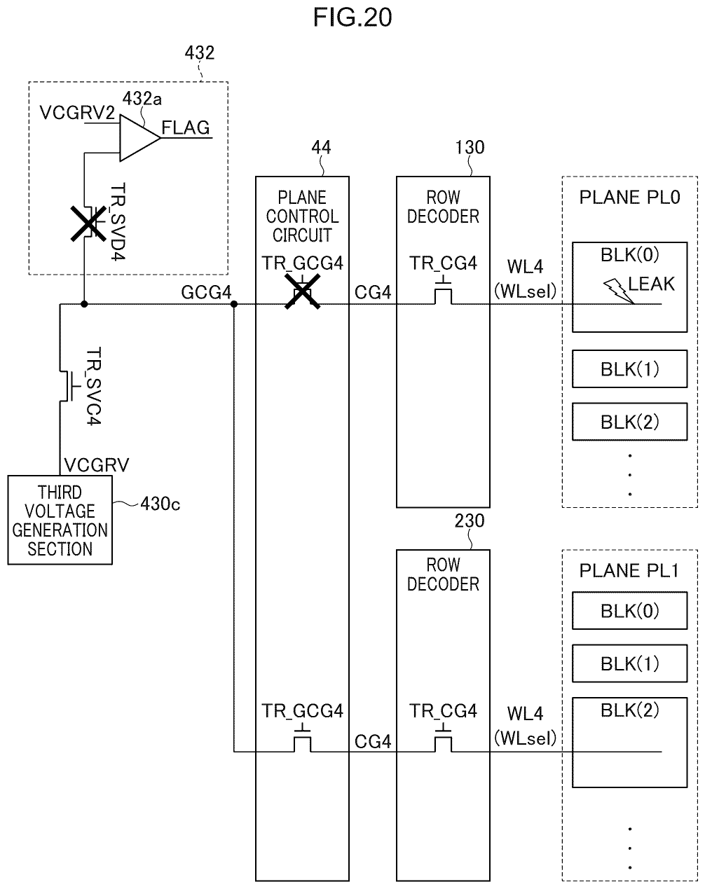

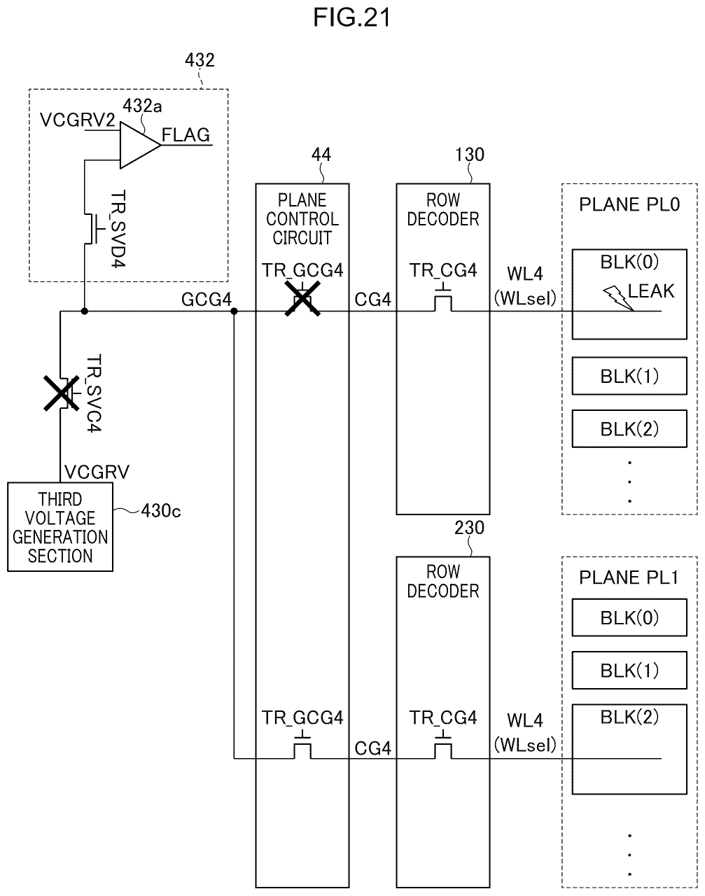

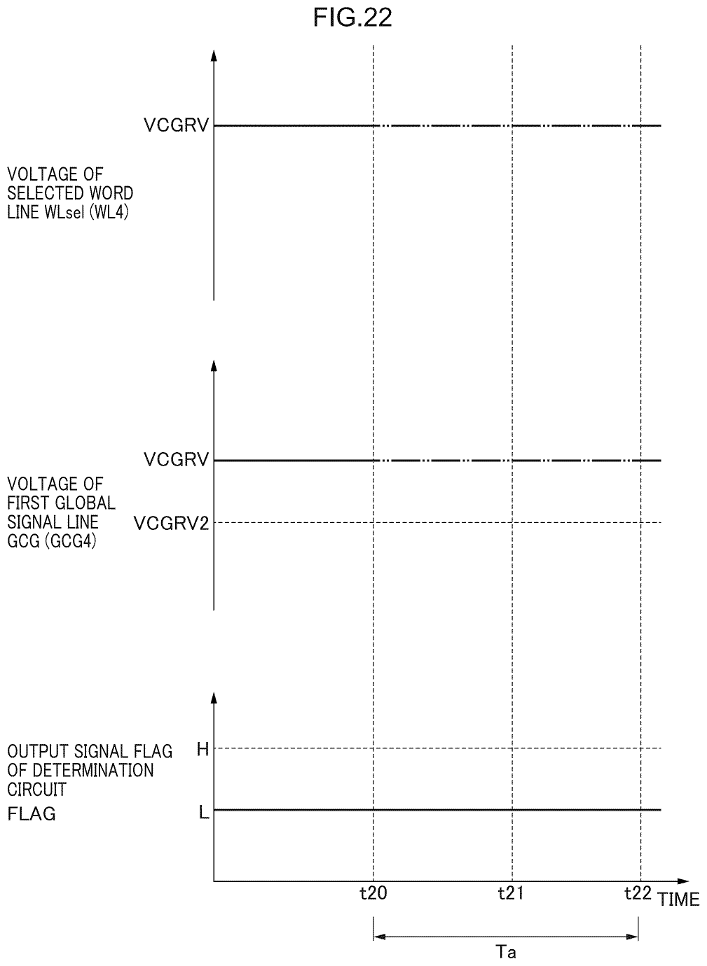

Next, as shown in FIG. 16, the sequencer 41 determines whether leakage checks on all the planes PL0 and PL1 have been completed (step S17). If the plane PL1 has not been checked for leakage (step S17: NO), the sequencer 41 returns to step S11 and similarly performs the processes of steps S11 to S16 for the plane PL1. As the processes of steps S11 and S12 are performed, the voltage VCGRV generated by the third voltage generation section 430c is applied to the selected word line WL4 in the block BLK(2) of the plane PL1 via the first global signal line GCG4 and via the second global signal line CG4 for the plane PL1 as shown in FIG. 20. In FIG. 9, the time at which the voltage VCGRV is applied to the selected word line WL4 in the block BLK(2) of the plane PL1 is shown as being t13. Besides, as the process of step S13 shown in FIG. 16 is performed, the first global signal line GCG4 enters a floating state as shown in FIG. 21. In so doing, if there is no leakage, for example, in the word line WL4 in the block BLK(2) of the plane PL1, as the processes of steps S14 to S16 shown in FIG. 16 are performed, the voltage of the selected word line WL4 in the block BLK(2) of the plane PL1, the voltage of the first global signal line GCG4, and the output signal FLAG of the determination circuit 432 change as shown in the upper part, middle part, and lower part of FIG. 22, respectively. Note that in FIG. 22, transitions after the first global signal line GCG4 enters a floating state at time t20 are indicated by chain double-dashed lines.

As shown in FIG. 22, after the first global signal line GCG4 enters a floating state at time t20, the voltage of the first global signal line GCG4 is kept at VCGRV. Therefore, the voltage of the first global signal line GCG4 remains higher than the reference voltage VCGRV2, the output signal FLAG of the comparison circuit 432a remains at logic low. Therefore, when the sequencer 41 acquires the output signal FLAG of the determination circuit 432 at time t22 after a lapse of the predetermined time period Ta from time t20, the output signal FLAG is logic low. The sequencer 41 stores correspondence between the acquired output signal FLAG and the block BLK(2) of the plane PL1 in a non-illustrated internal register in the sequencer 41.

When each of the planes PL0 and PL1 has been checked for leakage, in the process of step S17 shown in FIG. 16, the sequencer 41 determines that all the planes PL0 and PL1 have been checked for leakage (step S17: YES). Consequently, based on the correspondence between the respective blocks BLK(0) and BLK(2) of the planes PL0 and PL1 and the output signal FLAG of the determination circuit 432, the sequencer 41 determines whether leakage has been detected in one or more blocks (step S18).

As described above, when the output signal FLAG for the block BLK(2) of the plane PL1 is logic low, the sequencer 41 determines that there is no leakage in the block BLK(2) of the plane PL1. On the other hand, when the output signal FLAG for the block BLK(0) of the plane PL0 is logic high, the sequencer 41 determines that there is leakage in the block BLK(0) of the plane PL0. Therefore, the sequencer 41 determines that leakage has been detected in one or more blocks (step S18: YES). In this case, the sequencer 41 performs bad block handling for the block BLK(0) of the plane PL0 determined to be suffering leakage (step S19) and performs “failed” status handling for the block BLK(2) of the plane PL1 determined to be free of leakage (step S20).

Specifically, as the bad block handling in step S19, the sequencer 41 stores information that the block BLK(0) of the plane PL0 determined to be suffering leakage is a bad block in the status register 42c. The sequencer 41 also stores, as the “failed” status handling in step S20, information that the block BLK(2) of the plane PL1 determined to be free of leakage as a victim block in the status register 42c.

When stored in the status register 42c, information such as described above is stored in the ROM blocks in the respective memory cell arrays 110 and 210 of the planes PL0 and PL1. Consequently, for example, during a power-on-read process, by reading data from the ROM block of the memory cell array 110, the memory controller 1 acquires information that the block BLK(0) of the plane PL0 is a bad block. Consequently, the memory controller 1 excludes the block BLK(0) of the plane PL0 from subsequent operations.

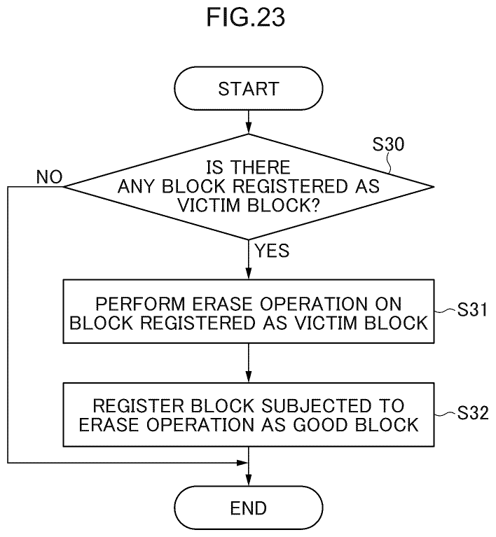

On the other hand, by reading data from the ROM block of the memory cell array 210, for example, during a power-on-read process, the memory controller 1 acquires information that the block BLK(2) of the plane PL1 is a victim block. In this case, the memory controller 1 performs a process such as shown in FIG. 23.

As shown in FIG. 23, the memory controller 1 determines whether there is any block registered as a victim block (step S30). If there is any block registered as a victim block (step S30: YES), the memory controller 1 performs an erase operation on the block registered as a victim block (step S31). Thus, if the block BLK(2) of the plane PL1 is a victim block such as described above, an erase operation is performed on the block BLK(2) of the plane PL1.

Then, the memory controller 1 registers the block BLK(2) of the plane PL1 subjected to the erase operation as a good block (step S32). Specifically, the memory controller 1 registers information that the block BLK(2) is a good block in the ROM block of the memory cell array 210 of the plane PL1.

Whereas the processes shown in FIG. 16 have been described above by taking as an example a case in which write operations are performed simultaneously into the memory cell transistor MT4 in the block BLK(0) of the plane PL0 and into the memory cell transistor MT4 in the block BLK(2) of the plane PL1, the processes shown in FIG. 16 can similarly be performed when write operations are performed simultaneously into another memory cell transistor MT in the block BLK(0) of the plane PL0 and into another memory cell transistor MT in the block BLK(2) of the plane PL1. Besides, the processes shown in FIG. 16 can similarly be performed when write operations are performed simultaneously into another block BLK of the plane PL0 and into another block BLK of the plane PL1.

### 1.12 Actions and Effects of Semiconductor Storage Device

As described above, the semiconductor storage device 2 according to the present embodiment includes the plane PL0 (first plane), the plane PL1 (second plane), the first global signal lines GCG0 to GCG7, the determination circuit 432, and the sequencer 41 (control unit). The planes PL0 and PL1 each include a plurality of blocks BLK, each of which is a set of a plurality of memory cell transistors MT. The first global signal lines GCG0 to GCG7 apply voltages to the word lines WL0 to WL7 (first word lines) connected to the gates of the memory cell transistors MT (first memory cell transistors) included in the block BLK (first block) of the plane PL0 and the word lines WL0 to WL7 (second word lines) connected to the gates of the memory cell transistors MT (second memory cell transistors) included in the block BLK (second block) of the plane PL1. Based on the voltages of the first global signal lines GCG0 to GCG7, the determination circuit 432 determines whether there is any leakage in the word lines WL0 to WL7 on the block BLK of the plane PL0 or in the word lines WL0 to WL7 on the block BLK of the plane PL1. The sequencer 41 controls the planes PL0 and PL1. If determination results produced by the determination circuit 432 indicate, for example, that there is leakage in the word line WL4 in the block BLK(0) of the plane PL0 and that there is no leakage in the word line WL4 in the block BLK(2) of the plane PL1, the sequencer 41 registers the block BLK(0) of the plane PL0 as a bad block and registers the block BLK(2) of the plane PL1 as a victim block able to be used as a good block.

With this configuration, the block BLK(2) of the plane PL1 likely to be determined together collaterally with the block BLK(0) of the plane PL0 as being a bad block can be used as a good block. This makes it possible to improve the block usage efficiency of the semiconductor storage device 2.

The semiconductor storage device 2 further includes the transistors TR_GCG0 to TR_GCG7 (first switching elements) corresponding to the plane PL0, the transistors TR_GCG0 to TR_GCG7 (second switching elements) corresponding to the plane PL1, the voltage generation section 430c (voltage generation circuit), and the transistors TR_SVC0 to TR_SVC7 (third switching elements). The transistors TR_GCG0 to TR_GCG7 corresponding to the plane PL0 are provided between the first global signal lines GCG0 to GCG7 and the plane PL0. The transistors TR_GCG0 to TR_GCG7 corresponding to the plane PL1 are provided between the first global signal lines GCG0 to GCG7 and the plane PL1. The voltage generation section 430c applies voltages to the first global signal lines GCG0 to GCG7. The transistors TR_SVC0 to TR_SVC7 are provided between the first global signal lines GCG0 to GCG7 and the voltage generation section 430c. The determination circuit 432 applies the predetermined voltage VCGRV to the first global signal line GCG4, for example, from the voltage generation section 430c, then turns on the transistor TR_GCG4 corresponding to the plane PL0, thereby connecting the first global signal line GCG4 to the word line WL4 in the block BLK(0) of the plane PL0. Then, the determination circuit 432 turns off the transistor TR_GCG4 and transistor TR_SVC4 corresponding to the plane PL1, thereby putting the first global signal line GCG4 in an electrically floating state. Then, based on the resulting voltage (first voltage) of the first global signal line GCG4, the determination circuit 432 determines whether there is any leakage in the word line WL4 in the block BLK(0) of the plane PL0. After applying the predetermined voltage VCGRV to the first global signal line GCG4, for example, from the voltage generation section 430c, the determination circuit 432 turns on the transistor TR_GCG4 corresponding to the plane PL1, thereby connecting the first global signal line GCG4 to the word line WL4 in the block BLK(2) of the plane PL1. Then, the determination circuit 432 turns off the transistor TR_GCG4 and transistor TR_SVC4 corresponding to the plane PL1, thereby putting the first global signal line GCG4 in an electrically floating state. Then, based on the resulting voltage (second voltage) of the first global signal line GCG4, the determination circuit 432 determines whether there is any leakage in the word line WL4 in the block BLK(2) of the plane PL1.

This configuration makes it possible to easily determine whether there is any leakage in the word line WL4 in the block BLK(0) of the plane PL0 or in the word line WL4 in the block BLK(2) of the plane PL1.

The determination circuit 432 includes the comparison circuit 432a. The comparison circuit 432a compares the voltage of the first global signal lines GCG0 to GCG7 with the predetermined reference voltage VCGRV2, and outputs a signal FLAG indicating the comparison results. The comparison circuit 432a connects, for example, the first global signal line GCG4 to the word line WL4 in the block BLK(0) of the plane PL0, compares the voltage (first voltage) of the first global signal line GCG4 with the reference voltage VCGRV2 when the first global signal line GCG4 is placed in an electrically floating state, and thereby outputs a signal FLAG that indicates whether there is any leakage in the word line WL4 (first word line) in the block BLK(0) of the plane PL0. The comparison circuit 432a connects, for example, the first global signal line GCG4 to the word line WL4 in the block BLK(2) of the plane PL1, compares the voltage (second voltage) of the first global signal line GCG4 with the reference voltage VCGRV2 when the first global signal line GCG4 is placed in an electrically floating state and thereby outputs a signal FLAG that indicates whether there is any leakage in the word line WL4 (second word line) in the block BLK(2) of the plane PL1.

With this configuration, the signal FLAG is output appropriately from the determination circuit 432, indicating whether there is any leakage in the word lines WL0 to WL7 in the blocks BLK of the planes PL0 and PL1.

The semiconductor storage device 2 further includes the transistors TR_SVD0 to TR_SVD7 (fourth switching elements) provided between the comparison circuit 432a and the first global signal lines GCG0 to GCG7. When the determination circuit 432 is not determining whether there is any leakage in the word lines WL0 to WL7 in the blocks BLK of the plane PL0 or in the word lines WL0 to WL7 in the blocks BLK of the plane PL1, the sequencer 41 turns off the transistors TR_SVD0 to TR_SVD7. When the determination circuit 432 determines whether there is any leakage in the word lines WL0 to WL7 in the blocks BLK of the plane PL0 or in the word lines WL0 to WL7 in the blocks BLK of the plane PL1, the sequencer 41 turns on the transistors TR_SVD0 to TR_SVD7.

This configuration makes it possible to prevent current leakage from the first global signal lines GCG0 to GCG7 to the comparison circuit 432a when it is not being determined whether there is any leakage.

After performing write operations, for example, into the memory cell transistor MT4 (first memory cell transistor) in the block BLK(0) of the plane PL0 and into the memory cell transistor MT4 (second memory cell transistor) in the block BLK(1) of the plane PL1, the sequencer 41 performs a leakage determination process using the determination circuit 432.

With this configuration, the leakage determination process can be performed more appropriately.

If, for example, the block BLK(2) of the plane PL1 has been registered as a victim block, the memory controller 1 performs an erase operation on the block BLK(2) of the plane PL1 before registering the block BLK(2) as a good block.

With this configuration, even if the block BLK(2) of the plane PL1, which is a good block, changes once to “failed” status, the block BLK(2) can be reused.

### 2 Other Embodiments

The present disclosure is not limited to the specific examples described above.

For example, the period of leakage checks used in the process of step S10 shown in FIG. 16 can be changed as appropriate. Possible examples of leakage check periods include a period during which the semiconductor storage device 2 is not in use and a period during which the semiconductor storage device 2 is not performing any of the write operation, read operation, and erase operation.

The number of planes of the semiconductor storage device 2 is not limited to two, and may be changed as desired.

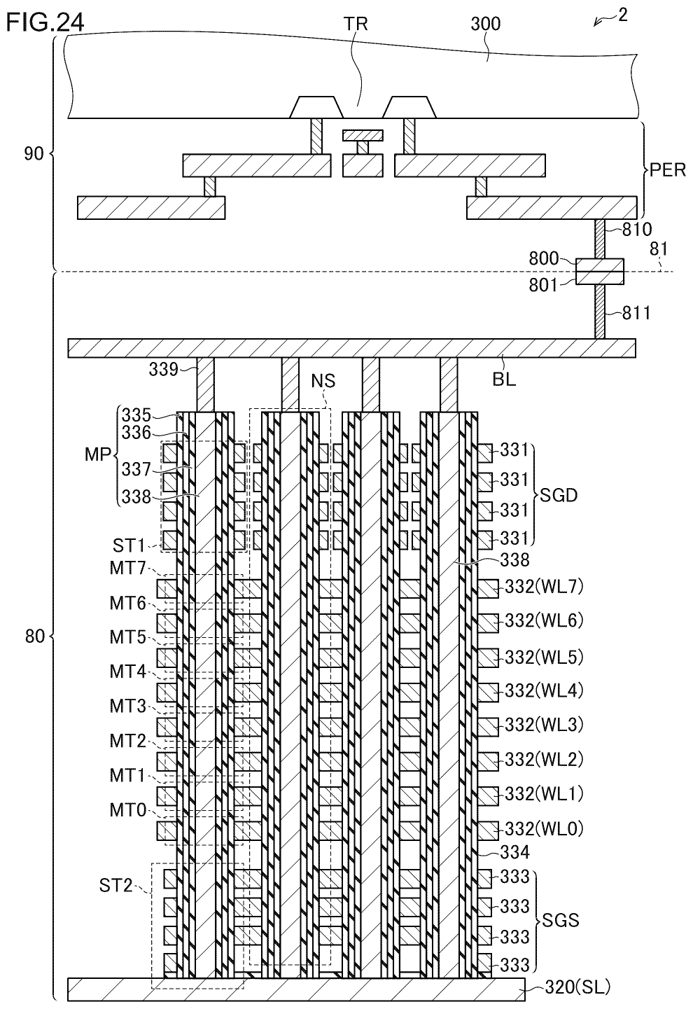

The structure of the semiconductor storage device 2 is not limited to the one shown in FIG. 5, and can be changed as appropriate. For example, the semiconductor storage device 2 may have a CBA (CMOS bonding array) structure such as shown in FIG. 24. In the case of the semiconductor storage device 2 shown in FIG. 24, a memory section 80 in which the memory cell array 110 is provided and a control circuit section 90 in which peripheral circuitry PER is provided are manufactured separately. The semiconductor storage device 2 is constructed by bonding together the memory section 80 and the control circuit section 90 via a bonding surface B1, with the memory section 80 and the control circuit section 90 having been manufactured separately. The memory cell array 110 and the peripheral circuitry PER are electrically connected with each other via interconnect layers 800 and 801 and vias 810 and 811 provided on the bonding surface B1.

While certain embodiments have been described, these embodiments have been presented by way of example only, and are not intended to limit the scope of the inventions. Indeed, the novel devices and methods described herein may be embodied in a variety of other forms; furthermore, various omissions, substitutions and changes in the form of the embodiments described herein may be made without departing from the spirit of the inventions. The accompanying claims and their equivalents are intended to cover such forms or modification as would fall within the scope and spirit of the inventions.

What is claimed is:

1. A semiconductor storage device comprising:
a first plane and a second plane, each including a plurality of blocks, each of which is a set of a plurality of memory cell transistors;
a signal line configured to apply voltages to a first word line connected to a gate of a first memory cell transistor contained in a first block of the first plane and a second word line connected to a gate of a second memory cell transistor contained in a second block of the second plane;
a determination circuit configured to determine based on the voltage of the signal line whether there is any leakage in the first word line or the second word line; and
a control unit configured to control the first plane and the second plane, wherein
when determination results produced by the determination circuit indicate that there is leakage in the first word line and that there is no leakage in the second word line, the control unit registers the first block as a bad block and registers the second block as a victim block able to be used as a good block.

2. The semiconductor storage device according to claim 1, further comprising:
a first switching element provided between the signal line and the first plane;
a second switching element provided between the signal line and the second plane;
a voltage generation circuit configured to apply a voltage to the signal line; and
a third switching element provided between the signal line and the voltage generation circuit,
wherein the determination circuit:
applies a predetermined voltage to the signal line from the voltage generation circuit, then turns on the first switching element, thereby connecting the signal line to the first word line, turns off the second switching element and the third switching element, thereby placing the signal line in an electrically floating state, and determines based on a resulting first voltage of the signal line whether there is any leakage in the first word line, and
applies the predetermined voltage to the signal line from the voltage generation circuit, then turns on the second switching element, thereby connecting the signal line to the gate of the second memory cell transistor, turns off the first switching element and the third switching element, thereby placing the signal line in an electrically floating state, and determines based on a resulting second voltage of the signal line whether there is any leakage in the second word line.

3. The semiconductor storage device according to claim 2, wherein:
the determination circuit includes a comparison circuit configured to compare the voltage of the signal line with a predetermined reference voltage and output a signal indicating comparison results; and
the comparison circuit
compares the first voltage of the signal line with the reference voltage and thereby outputs a signal indicating whether there is any leakage in the first word line, and
compares the second voltage of the signal line with the reference voltage and thereby outputs a signal indicating whether there is any leakage in the second word line.

4. The semiconductor storage device according to claim 3, wherein the reference voltage is equal to or lower than the predetermined voltage.

5. The semiconductor storage device according to claim 3, further comprising a fourth switching element provided between the comparison circuit and the signal line.

6. The semiconductor storage device according to claim 5, wherein the control unit:
turns off the fourth switching element when the determination circuit is not determining whether there is any leakage in the first word line or the second word line, and
turns on the fourth switching element when the determination circuit determines whether there is any leakage in the first word line or the second word line.

7. The semiconductor storage device according to claim 1, wherein the control unit performs write operations into the first memory cell transistor and the second memory cell transistor, and then performs a determination process using the determination circuit to check whether there is any leakage in the first word line or the second word line.

8. A memory system comprising:
a semiconductor storage device including a first plane and a second plane, each including a plurality of blocks, each of which is a set of a plurality of memory cell transistors; and
a memory controller configured to control the semiconductor storage device,
wherein the semiconductor storage device includes:
a signal line configured to apply voltages to a first word line connected to a gate of a first memory cell transistor contained in a first block of the first plane and a second word line connected to a gate of a second memory cell transistor contained in a second block of the second plane,
a determination circuit configured to determine based on the voltage of the signal line whether there is any leakage in the first word line or the second word line, and
a control unit configured to register the first block as a bad block and register the second block as a victim block able to be used as a good block, when determination results produced by the determination circuit indicate that there is leakage in the first word line and that there is no leakage in the second word line, and
when the second block is registered as the victim block, the memory controller performs an erase operation on the second block and then registers the second block as a good block.

9. A method for controlling a semiconductor storage device that includes:
a first plane and a second plane, each including a plurality of blocks, each of which is a set of a plurality of memory cell transistors;
a signal line configured to apply voltages to a first word line connected to a gate of a first memory cell transistor contained in a first block of the first plane and a second word line connected to a gate of a second memory cell transistor contained in a second block of the second plane,
a determination circuit configured to determine based on the voltage of the signal line whether there is any leakage in the first word line or the second word line, and
a control unit configured to control the first plane and the second plane, wherein
when determination results produced by the determination circuit indicate that there is leakage in the first word line and that there is no leakage in the second word line, the control unit registers the first block as a bad block and registers the second block as a victim block.
